(19) United States
(12) Patent Application Publication
(10) Pub. No.: US 2026/0005003 A1
(43) Pub. Date: Jan. 1, 2026

(54) TEMPERATURE CONTROL SYSTEM

(71) Applicant: Samsung Electronics Co., Ltd., Suwon-si (KR)

(72) Inventors: Akira GOTO, Yokohama-shi (JP); Naoyuki TAKADA, Yokohama-shi (JP)

(73) Assignee: Samsung Electronics Co., Ltd., Suwon-si (KR)

(21) Appl. No.: 19/219,491

(22) Filed: May 27, 2025

(30) Foreign Application Priority Data
Jun. 28, 2024 (JP) 2024-104712
Oct. 24, 2024 (KR) 10-2024-0146854

(51) Int. Cl. H01J 37/32; G05D 23/13

(52) U.S. Cl. CPC H01J 37/32724; G05D 23/1393; H01J 2237/002; H01J 2237/334

(57) ABSTRACT

A temperature control system includes a temperature control base bonded to a bottom of a maintenance plate, a first chiller configured to control a temperature of a first fluid, a second chiller configured to control a temperature of a second fluid, a temperature control unit configured to heat or cool the first fluid or the second fluid flowing into a flow path defined in the temperature control base to have a target temperature, and a distribution-direction switching unit configured to control a distribution direction of each fluid. The distribution-direction switching unit distributes the second fluid in a first direction from a central side of the temperature control base toward an outer circumferential side in a temperature raising operation, and distributes the first fluid in a second direction opposite to the first direction in a temperature lowering operation.

### CROSS-REFERENCE TO RELATED APPLICATION(S)

This application claims benefit of priority to Korean Patent Application No. 10-2024-0146854 filed on Oct. 24, 2024 and Japanese Patent Application No. 2024-104712 filed on Jun. 28, 2024 in the Japan Patent Office, the disclosures of which are incorporated herein by reference in their entirety.

### BACKGROUND

Example embodiments of the present disclosure relate to temperature control systems connected to a plasma processing device performing plasma etching.

In an etching process for a three-dimensional (3D) NAND memory or DRAM in semiconductor manufacturing, an etching technique with a high-aspect-ratio may be desired. As a method for increasing an etching rate in an etching process, cryo-etching, which performs dry etching in an extremely low-temperature environment (cryo-environment) of −40° C. or lower, may be used.

In this process, reaction products (e.g., deposits) generated during etching may be deposited and attached to the entire surface of an exposed surface in a vacuum chamber. Because the deposits may become a factor causing defects by being peeled off during etching and attached to work, a process for removing the deposits may be performed after the etching process ends.

As a removal process, plasma cleaning which removes deposits using O₂ plasma may be used. In plasma cleaning, the higher the temperature, the higher the removal efficiency. Accordingly, in the removal process, it may be desirable to raise a low-temperature maintenance plate maintained in a cryogenic environment to a higher temperature.

In a plasma processing device, performance desired when switching a maintenance plate maintaining a work from a relatively low temperature to a relatively high temperature may include switching with relatively high throughput by shortening the process time so as to not hinder productivity, and reducing or preventing damage to components due to temperature changes. To increase the etching rate of plasma etching and/or to improve efficiency of the removal process, it may be desired to determine a fluid for controlling the temperature of the maintenance plate to be, for example, about −50° C. or lower for a relatively low temperature and about 50° C. or higher for a relatively high temperature, and to switch between the relatively low temperature and the relatively high temperature at a relatively high speed.

However, when fluids having a wide temperature range as above are switched and used, the relatively low-temperature fluid and the relatively high-temperature fluid may be suddenly switched such that temperature distribution of the maintenance plate may become uneven, and the maintenance plate may be broken due to thermal stress.

As a method for reducing the unevenness in temperature distribution, the temperature of the fluid may be controlled to be gradually changed, for example, but it take a relatively long time until the target temperature is reached, which may reduce productivity.

### SUMMARY

Some example embodiments of the present disclosure provide temperature control systems which may reduce or prevent damage to components due to rapid temperature changes during temperature control while shortening the temperature control time.

According to an example embodiment of the present disclosure, a temperature control system connected to a plasma processing device, which is configured to perform plasma etching on a work in a vacuum chamber, may include a temperature control base bonded to a bottom of a maintenance plate in the vacuum chamber, the temperature control base including a flow path through which fluid is distributed, the maintenance plate being in the vacuum chamber and configured to support the work thereon and fixed to a lower body of the vacuum chamber, a first chiller configured to supply a first fluid controlled to a first temperature, a second chiller configured to supply a second fluid controlled to a second temperature different from the first temperature, and a fluid supply control unit configured to selectively supply the first fluid from the first chiller or the second fluid from the second chiller to the temperature control base, wherein the fluid supply control unit includes a distribution-direction switching unit configured to control a distribution direction of each of the first fluid and the second fluid, and wherein the distribution-direction switching unit is configured to distribute the second fluid in a first direction when the temperature is increased, and distribute the first fluid in a second direction when the temperature is decreased, the first directing being from a central side of the temperature control base toward an outer circumferential side of the temperature control base, the second direction being from the outer circumferential side of the temperature control base toward the central side of the temperature control base.

According to an example embodiment of the present disclosure, a temperature control system connected to a plasma processing device, which is configured to perform plasma etching on a work in a vacuum chamber, may include a temperature control base bonded to a bottom of a maintenance plate in the vacuum chamber, the maintenance plate being in the vacuum chamber and configured to support the work thereon and fixed to a lower body of the vacuum chamber, and the temperature control base including a flow path through which fluid is distributed, a first chiller configured to supply a first fluid having a first temperature, a second chiller configured to supply a second fluid having a second temperature higher than the first temperature, a temperature adjustment unit configured to heat or cool the first fluid or the second fluid flowing into the temperature control base, and a distribution-direction switching unit configured to control a distribution direction of each of the first fluid and the second fluid, wherein the distribution-direction switching unit is configured to distribute the second fluid in a first direction in a temperature raising operation, and distribute the first fluid in a second direction in a temperature lowering operation, the first directing being from a central side of the temperature control base toward an outer circumferential side of the temperature control base, the second direction being from the outer circumferential side of the temperature control base toward the central side of the temperature control base

According to an example embodiment of the present disclosure, a temperature control system connected to a plasma processing device, which is configured to perform plasma etching on a work in a vacuum chamber, may include a temperature control base bonded to a bottom of a maintenance plate in the vacuum chamber, the temperature control base including a flow path through which fluid is distributed, the maintenance plate being in the vacuum chamber and configured to support the work thereon and fixed to a lower body of the vacuum chamber, a first chiller configured to supply a first fluid controlled to a first temperature, a first valve between the first chiller and the temperature control base, a second chiller configured to supply a second fluid controlled to a second temperature different from the first temperature, a second valve between the second chiller and the temperature control base, and a fluid supply control unit configured to selectively supply at least one of the first fluid from the first chiller or the second fluid from the second chiller to the temperature control base, wherein the fluid supply control unit includes a distribution-direction switching unit configured to control a distribution direction of each of the first fluid and the second fluid, wherein, in a temperature raising operation, the second valve is configured to be opened to allow distribution of the second fluid to the temperature control base, and the distribution-direction switching unit is configured to distribute the second fluid in a first direction from a central side of the temperature control base to an outer circumferential side, and wherein, in a temperature lowering operation, the first valve is configured to be opened to allow distribution of the first fluid the temperature control base, and the distribution-direction switching unit is configured to distribute the first fluid in a second direction from the outer circumferential side of the temperature control base toward the central side of the temperature control base.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a diagram illustrating a plasma processing device to which a temperature control system is connected, according to an example embodiment of the present disclosure;

FIG. 2 is a functional block diagram illustrating a temperature control system, according to an example embodiment of the present disclosure;

FIG. 3A is a diagram illustrating a first direction of a flow path;

FIG. 3B is a diagram illustrating a second direction of a flow path;

FIG. 4A is a diagram illustrating a flow of fluid in a low-temperature maintenance operation of a temperature control system of FIG. 2;

FIG. 4B is a diagram illustrating a flow of fluid in a temperature raising operation of a temperature control system of FIG. 2;

FIG. 4C is a diagram illustrating a flow of fluid in a high-temperature maintenance operation of a temperature control system of FIG. 2;

FIG. 4D is a diagram illustrating a flow of fluid in a temperature lowering operation of a temperature control system of FIG. 2;

FIG. 5 is a functional block diagram illustrating a temperature control system according to an example embodiment of the present disclosure;

FIG. 6A is a diagram illustrating a flow of fluid of a low-temperature maintenance operation of a temperature control system of FIG. 5;

FIG. 6B is a diagram illustrating a flow of fluid of a temperature raising operation of a temperature control system of FIG. 5;

FIG. 6C is a diagram illustrating a flow of fluid of a high-temperature maintenance operation of a temperature control system of FIG. 5;

FIG. 6D is a diagram illustrating a flow of fluid of a temperature lowering operation of a temperature control system of FIG. 5;

FIG. 7 is a functional block diagram illustrating a temperature control system according to an example embodiment of the present disclosure;

FIG. 8A is a diagram illustrating a flow of fluid of a low-temperature maintenance operation of a temperature control system of FIG. 7;

FIG. 8B is a diagram illustrating a flow of fluid of a temperature raising operation of a temperature control system of FIG. 7;

FIG. 8C is a diagram illustrating a flow of fluid of a high-temperature maintenance operation of a temperature control system of FIG. 7;

FIG. 8D is a diagram illustrating a flow of fluid of a temperature lowering operation of a temperature control system of FIG. 7;

FIG. 9A is a diagram illustrating a simulation result of an example embodiment, illustrating distribution of temperature of an electrostatic chuck after 10 seconds;

FIG. 9B is a diagram illustrating a simulation result of an example embodiment, illustrating distribution of temperature of an electrostatic chuck after 20 seconds;

FIG. 9C is a diagram illustrating a simulation result of an example embodiment, illustrating distribution of temperature of an electrostatic chuck after 30 seconds;

FIG. 9D is a diagram illustrating a simulation result of an example embodiment, illustrating distribution of temperature of an electrostatic chuck after 60 seconds;

FIG. 10A is a diagram illustrating a simulation result of a comparative example, illustrating distribution of temperature of an electrostatic chuck after 10 seconds;

FIG. 10B is a diagram illustrating a simulation result of a comparative example, illustrating distribution of temperature of an electrostatic chuck after 20 seconds;

FIG. 10C is a diagram illustrating a simulation result of a comparative example, illustrating distribution of temperature of an electrostatic chuck after 30 seconds;

FIG. 10D is a diagram illustrating a simulation result of an example embodiment, illustrating distribution of temperature of an electrostatic chuck after 60 seconds;

FIG. 11A is a diagram illustrating a simulation result indicating distribution of stress of an electrostatic chuck of an example embodiment; and

FIG. 11B is a diagram illustrating a simulation result indicating distribution of stress of an electrostatic chuck of a comparative example.

### DETAILED DESCRIPTION

Hereinafter, some example embodiments of the present disclosure will be described as below with reference to the accompanying drawings.

In the drawings, same elements will be indicated by same reference numerals. Also, redundant descriptions and detailed descriptions of known functions and elements that may unnecessarily make the gist of the present disclosure obscure will be omitted. In the accompanying drawings, some elements may be exaggerated.

In the example embodiments, the terms “upper portion” or “upper” may include “disposed on and in direct contact with and” and also “disposed on and not in contact with.” Also, the terms “lower portion” or “lower” may include “disposed below and in direct contact with and” and also “disposed below and not in contact with.”

An expression used in the singular encompasses the expression of the plural, unless it has a clearly different meaning in the context. The terms, “include,” “comprise,” “is configured to,” or the like of the description are used to indicate the presence of features, numbers, steps, operations, elements, portions or combination thereof, and do not exclude the possibilities of combination or addition of one or more features, numbers, steps, operations, elements, portions or combination thereof.

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those determined forth herein, but may be changed as will be apparent to one of ordinary skill in the art, with the exception of operations necessarily occurring in a certain order.

Further, the terms “first,” “second,” and the like may be used to distinguish one element from the other, and may not limit a sequence and/or an importance, or others, in relation to the elements.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., +10%).

When the term “about,” “substantially” or “approximately” is used in this specification in connection with a numerical value, it is intended that the associated numerical value includes a manufacturing or operational tolerance (e.g., +10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes.

As used herein, expressions such as “one of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

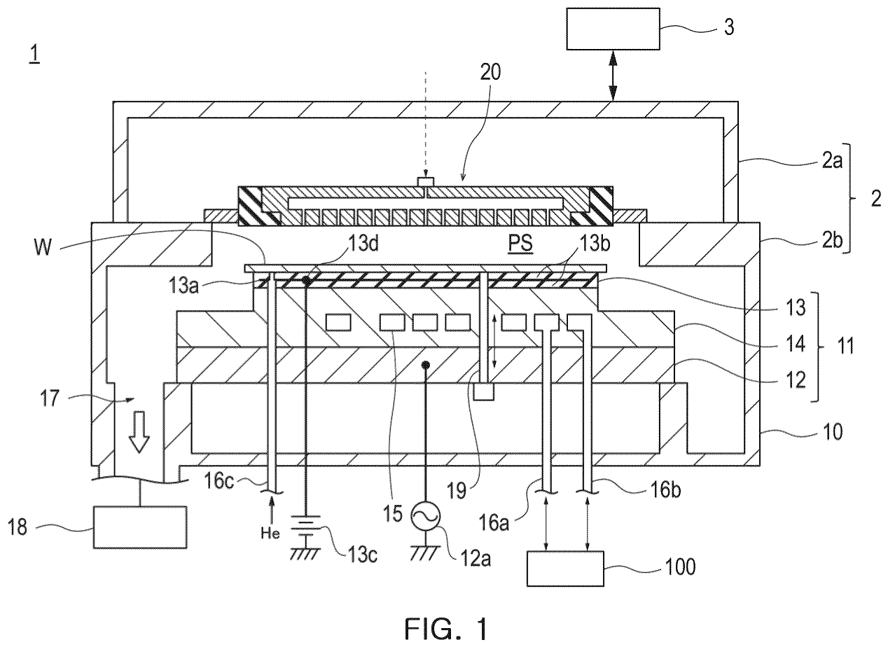

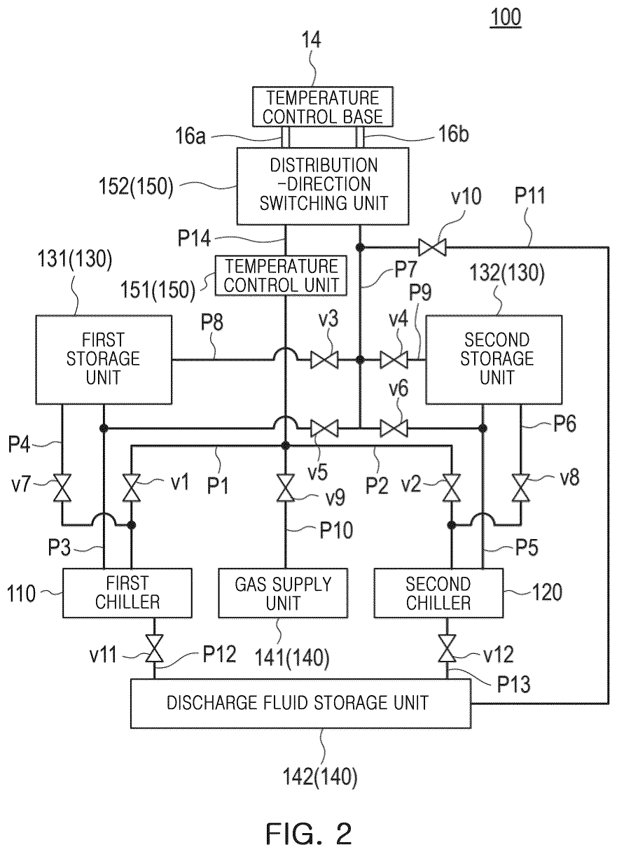

FIG. 1 illustrates the a processing device 1 to which a temperature control system 100 is connected, according to an example embodiment of the present disclosure. FIG. 2 is a block diagram illustrating a flow of fluid of the temperature control system 100, according to an example embodiment of the present disclosure.

The temperature control system 100 may be connected to the plasma processing device 1 for performing plasma etching. The temperature control system 100 may control a temperature of an electrostatic chuck 13, which functions as a maintenance plate disposed on a stage 11 of the plasma processing device 1, to be a target temperature.

As illustrated in FIG. 1, the plasma processing device 1 may include a device body 2 and a control device 3. The device body 2 may be divided into an upper body 2a and a lower body 2b, and a plasma process space PS may be formed therein. The upper body 2a and the lower body 2b may form a vacuum chamber 10 configured as a treatment vessel for performing a desired (or alternatively, predetermined) plasma treatment on a work W, such as a disk-shaped semiconductor wafer using silicon as a base material, by overlapping each other vertically. An exhaust path 17 may be formed in the vacuum chamber 10. An exhaust device 18 may be connected to the exhaust path 17 through an exhaust pipe. The exhaust device 18 may include, for example, a vacuum pump and may depressurize an inside of the vacuum chamber 10 to a desired (or alternatively, predetermined) vacuum level.

The control device 3 may include various processors, memories, input/output interfaces, or the like. The control device 3 may execute a desired (or alternatively, predetermined) program read from the memory by the processor and may output a control instruction to the control target through an input/output interface. Accordingly, the plasma processing device 1 may perform a desired (or alternatively, predetermined) plasma treatment, such as etching, on the work W. Also, the control device 3 may comprehensively perform control of a direction of fluid distribution, temperature control, or the like of each unit of the temperature control system 100 connected to the plasma processing device 1.

A stage 11 on which a work W to be treated may be mounted may be provided in the vacuum chamber 10. The stage 11 may include a lower electrode 12, an electrostatic chuck 13, and a temperature control base 14.

The lower electrode 12 may be formed of or include, for example, aluminum, and may be supported by a lower portion of the vacuum chamber 10 through an insulating member. The lower electrode 12 may be disposed as a pair with the upper electrode 20. A temperature control base 14 may be disposed on an upper portion of the lower electrode 12. High-frequency power may be supplied to the lower electrode 12 from a high-frequency power supply 12a.

The electrostatic chuck 13 may include an electrode 13a, which is a conductive film, and a pair of insulating plates 13b formed of or include ceramics such as Al₂O₃ and support the electrode 13a therebetween, and may be a maintenance plate fixing thereon the work W by electrostatic adsorption. The mounting surface of the electrostatic chuck 13 may form a plurality of convex portions for controlling attachment of particles. The electrostatic chuck 13 may be connected to a DC power supply 13c and a high voltage (HV) terminal 13d. The DC power supply 13c may supply a relatively high voltage desired when fixing the work W by electrostatic adsorption through the HV terminal 13d.

The electrostatic chuck 13 may be supplied with a heat-conducting gas such as, for example, He gas through a gas pipe 16c. The heat-conducting gas may be supplied between the electrostatic chuck 13 and the work W. The heat-conducting gas may adjust thermal conductivity between the electrostatic chuck 13 and the work W by adjusting the supply pressure.

The temperature control base 14 may be formed of or include metal such as Ti or Nb, may be disposed between the lower electrode 12 and the electrostatic chuck 13 and may be bonded to the electrostatic chuck 13. The temperature control base 14 may have a flow path 15 formed therein through which a fluid may be distributed to perform temperature control of the electrostatic chuck 13. As a material of the temperature control base 14, a material having a relatively small thermal expansion difference with respect to the material of the electrostatic chuck 13 may be selected, and the material of the temperature control base 14 may be formed of a non-metal.

The fluid distributing the flow path 15 may be a relatively low-temperature/relatively high-temperature fluid such as a first fluid or a second fluid functioning as a heat medium, or an inert compressed gas (discharge gas) for discharging the fluid in the flow path 15 externally of the flow path 15. The flow path 15 may be connected to a distribution-direction switching unit 152 of a fluid supply control unit 150, which will be described later, through a pipe 16a and a pipe 16b. The fluid may be supplied to the flow path 15 from the temperature control system 100 through the pipe 16a or the pipe 16b. The fluid flowing in the flow path 15 may return to the temperature control system 100 through the pipe 16a or the pipe 16b.

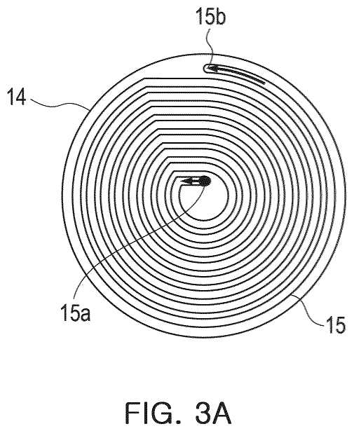

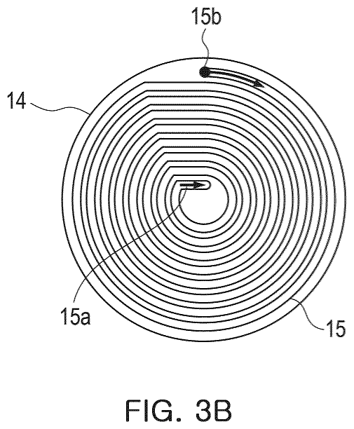

The flow path 15 may extend from a central side (or area) of the temperature control base 14 toward an outer circumferential side (or area). The flow path 15 may include a first distribution port 15a for allowing fluid to flow into a central side of the flow path 15 upon initiation of distribution of fluid as illustrated in FIGS. 3A and 3B, and a second distribution port 15b for allowing fluid to flow into the outer circumferential side of the flow path 15 upon initiation of distribution. The flow path 15 illustrated in FIGS. 3A and 3B may be formed such that the first distribution port 15a formed near the center is connected to the second distribution port 15b formed on the outer circumferential side in a roughly concentric spiral shape in a single stroke manner throughout the entire temperature control base 14. In the example embodiment, the first distribution port 15a may be connected to the pipe 16a, and the second distribution port 15b may be connected to the pipe 16b.

The shape of the flow path 15 illustrated in FIG. 3A and FIG. 3B is a conceptual diagram illustrating the function of the flow path 15, and is not limited to the illustrated example. The flow path 15 may be at least one flow path extending from the central side of the temperature control base 14 toward the outer circumferential side while circling over the entire base. Accordingly, the flow path 15 may include a shape such as meandering or partially folding in the middle, for example.

The fluid distributed in the temperature control base 14 may be distributed in two directions: a “first direction” from a central side of the temperature control base 14 toward the outer circumferential side, and a “second direction” from the outer circumferential side of the temperature control base 14 toward the central side. In the example embodiment, the first direction may be a direction in which fluid is flowed in from the first distribution port 15a of the flow path 15 and discharged from the second distribution port 15b as illustrated in FIG. 3A. In the example embodiment, the second direction may be a direction in which fluid is flowed in from the second distribution port 15b of the flow path 15 and discharged from the first distribution port 15a as illustrated in FIG. 3B.

The distribution direction of the fluid for the flow path 15 may be suitably switched under control of the distribution-direction switching unit 152 described later. In the example embodiment, the relatively low-temperature fluid may be distributed in the second direction, and the relatively high-temperature fluid may be distributed in the first direction. That is, the relatively low-temperature first fluid discharged from the first chiller 110 described later may flow in from the second distribution port 15b of the flow path 15 and may be discharged from the first distribution port 15a in the second direction. Also, the relatively high-temperature second fluid distributed from the second chiller 120 described later may flow in from the first distribution port 15a of the flow path 15 in the first direction and may be discharged from the second distribution port 15b. The discharge gas extruding the fluid remaining in the flow path 15 to the outside may be distributed in the first direction or the second direction.

The vacuum chamber 10 may include a lift pin 19 movable to a region above the mounting surface of the electrostatic chuck 13. The lift pin 19 may be configured to be movable in the vertical direction by a driving mechanism not illustrated. The work W may return to the stage 11 by a return device not illustrated and may be transferred to the lift pin 19 having moved to a region above the mounting surface of the electrostatic chuck 13. The lift pin 19 may be lowered and mounted on the mounting surface of the electrostatic chuck 13, and the work W may be absorbed to the electrostatic chuck 13 and may be maintained by an electrostatic force formed by a DC power applied from a DC power supply 13c.

An upper electrode 20 may be disposed at a position above the stage 11 and opposing the stage 11. The upper electrode 20 may be disposed to be almost or substantially parallel to the lower electrode 12. In the space between the upper electrode 20 and the lower electrode 12, plasma may be generated, and plasma treatment such as etching may be performed on the work W maintained on the electrostatic chuck 13 by the generated plasma.

The upper electrode 20 may be formed as a showerhead as a gas inlet port. The showerhead may be configured to allow at least one treatment gas from a treatment gas supply unit, not illustrated, to flow into the plasma process space PS. The showerhead may include at least one gas supply port, at least one gas diffusion chamber, and a plurality of gas inlet ports.

In the description below, a temperature control system 100 may be described.

The temperature control system 100 may be connected to the plasma processing device 1 and may perform temperature control of a maintenance plate (electrostatic chuck 13), on which the work W to be plasma treated is mounted, through a temperature control base 14. Each unit included in the temperature control system 100 may be driven and controlled according to a desired (or alternatively, predetermined) operation program by the control device 3.

The temperature control system 100 may include a first chiller 110, a second chiller 120, a storage unit 130, a fluid discharge unit 140, and a fluid supply control unit 150. The temperature control system 100 may also include a temperature control base 14 in which the fluid (e.g., first fluid and/or second fluid) discharged from the first chiller 110 or the second chiller 120 is distributed.

For ease of description, the fluid for temperature control distributed in the temperature control system 100 may be referred to as “first fluid” for the fluid controlled to a relatively low temperature in the first chiller 110, and “second fluid” for the fluid controlled to a relatively high temperature in the second chiller 120. However, the fluids may have different temperatures, and may be a single type of fluid distributed in the system.

The temperature control system 100 may include pipes P1-P14 such that fluid may be distributed. The temperature control system 100 may form a circulation path in the system by connecting each unit through the pipes P1-P14. Also, each of the pipes P1-P14 may be provided with valves v1-v12 functioning as partition valves for controlling whether to distribute each fluid. The valves v1-v12 may be opened and closed by the control device 3 such that the fluid may be distributed in a desired direction. The temperature control system 100 may control each valve such that when a fluid, a distribution target, reaches a target location, only the desired valves may be opened and the other valves may be closed in order to block or prevent mixing of other fluids while guiding the distribution direction.

The first chiller 110 may control the first fluid, which becomes a heat medium, to a desired (or alternatively, predetermined) temperature. The first chiller 110 may be connected to the temperature control unit 151 of the fluid supply control unit 150 through the pipe P1. The first chiller 110 may be connected to the distribution-direction switching unit 152 through the pipe P3. The pipe P3 may function as a flow path for directly returning the first fluid, which returns from the flow path 15, to the first chiller 110. In the example embodiment, the first fluid may use an insulating fluid such as Galden® functioning as a heat medium. A fluid that becomes a liquid in the temperature range used may be selected as the first fluid.

The first chiller 110 may cool the first fluid to a target temperature of the temperature control base 14, which is determined in the range of about −100° C. to about 0° C. The first chiller 110 may control the temperature of the first fluid to a temperature determined in a range up to about −10° C. with respect to the target temperature. The first fluid may be supplied to the temperature control base 14 such that the temperature of the electrostatic chuck 13 may decrease to a desired target temperature.

The second chiller 120 may control the second fluid, which is a heat medium, to a temperature different from that of the first fluid. The second chiller 120 may be connected to the temperature control unit 151 of the fluid supply control unit 150 through the pipe P2. The second chiller 120 may be connected to the distribution-direction switching unit 152 through the pipe P5. The pipe P5 may function as a flow path for directly returning the second fluid returning from the flow path 15 to the second chiller 120. In the example embodiment, the same fluid as the first fluid may be used as the second fluid.

The second chiller 120 may heat the second fluid to the target temperature of the temperature control base 14, which is determined in the range of about 40° C. to about 200° C. The second chiller 120 may control the temperature of the second fluid to a temperature determined in the range up to about +10° C. with respect to the target temperature. The second fluid may be supplied to the temperature control base 14 such that the temperature of the electrostatic chuck 13 may increase to the desired target temperature.

The storage unit 130 may be configured to include the first storage unit 131 and the second storage unit 132, and may be configured as a storage tank disposed on the upstream side of the direction of fluid distribution of the first chiller 110 and the second chiller 120. The storage unit 130 may store the return fluid from the temperature control base 14, may adjust the fluid to be equal to the control temperature of the first chiller 110 or the second chiller 122, and may return the fluid to the first chiller 110 or the second chiller 120. The storage unit 130 may function as a buffer element to block or prevent the temperature of the first fluid supplied from the first chiller 110 or the second fluid supplied from the second chiller 120 from changing from the control temperature.

The first storage unit 131 may be disposed upstream side of the first chiller 110. The first storage unit 131 may be connected to the first chiller 110 through the pipes P3 and P4. The first storage unit 131 may circulate the first fluid between the first chiller 110 and the first storage unit 131, and may adjust the temperature of the stored fluid to the control temperature of the first chiller 110.

The first storage unit 131 may be connected to the distribution-direction switching unit 152 through the pipe P8. The first storage unit 131 may store the first fluid supplied from the first chiller 110 as the return fluid returned from the temperature control base 14. Accordingly, the return fluid stored in the first storage unit 131 may be the first fluid.

The first storage unit 131 may adjust the temperature of the first fluid, which is the return fluid, to be equal to the control temperature of the first chiller 110. The first storage unit 131 may return the temperature-adjusted return fluid to the first chiller 110. The temperature adjustment of the return fluid in the first storage unit 131 may be controlled by the first chiller 110. As such, the first fluid returned from the first storage unit 131 may have a temperature equivalent to that of the first fluid in the first chiller 110 when the fluid returns to the first chiller 110. Accordingly, the first chiller 110 may supply the first fluid at a stable temperature.

When the temperature becomes equivalent to the control temperature of the first chiller 110, the return fluid returned to the first storage unit 131 may directly return to the first chiller 110 through the pipe P3. In the temperature control system 100, the pipe P3 may function as a bypass path not passing through the second storage unit 132.

The second storage unit 132 may be disposed on the upstream side of the second chiller 120. The second storage unit 132 may be connected to the second chiller 120 through the pipes P5 and P6. The second storage unit 132 may circulate the first fluid between the second chiller 120 and the second storage unit 132 and may adjust the temperature of the stored fluid to the control temperature of the second chiller 120.

The second storage unit 132 may be connected to the distribution-direction switching unit 152 through the pipe P9. The second storage unit 132 may store the second fluid supplied from the second chiller 120 as the return fluid returned from the temperature control base 14. Accordingly, the return fluid stored in the second storage unit 132 may be the second fluid.

The second storage unit 132 may adjust the temperature of the second fluid, which is the return fluid, to be equal to the control temperature of the second chiller 120. The second storage unit 132 may return the temperature-adjusted return fluid to the second chiller 120. The temperature adjustment of the return fluid in the second storage unit 132 may be temperature controlled by the second chiller 120. As such, the second fluid returned from the second storage unit 132 may have a temperature equivalent to that of the second fluid in the second chiller 120 when the fluid returns to the second chiller 120. Accordingly, the second chiller 120 may supply the second fluid at a stable temperature.

The return fluid to the second storage unit 132 may directly return to the second chiller 120 through the pipe P5 when the temperature is equal to the control temperature of the second chiller 120. In the temperature control system 100, the pipe P5 may function as a bypass path not passing through the second storage unit 132.

For example, when the temperature control base 14 in a relatively low-temperature state is rapidly heated, the second chiller 120 may supply the second fluid, heated to the target temperature, to the temperature control base 14. In this case, because the temperature control base 14 is in a relatively low-temperature state, the temperature of the supplied second fluid may be cooled after passing through the flow path 15. When the cooled second fluid directly returns to the second chiller 120, the fluid may lower the temperature of the second fluid in the second chiller 120 to the extent that the temperature adjustment may not catch up the temperature. Accordingly, the second chiller 120 may supply the second fluid at a temperature different from the target temperature, and it may take time to reach the target temperature. To address this issue, the temperature control system 100 in the example embodiment may store the return fluid from the temperature control base 14 in the second storage unit 132, may adjust the temperature to be equal to the control temperature of the second chiller 120, and may return the return fluid to the second chiller 120 as the second fluid. Accordingly, the second chiller 120 may constantly supply the second fluid adjusted to the target temperature without substantially affecting the temperature control time.

The fluid discharge unit 140 may include a gas supply unit 141 and a discharge fluid storage unit (alternatively referred to as a storage unit, a storage, or a discharge fluid storage) 142.

The gas supply unit 141 may supply an inert compressed gas to be the discharge gas to the flow path 15 connected to the temperature control base 14. The gas supply unit 141 may be connected to the fluid supply control unit 150 through the pipe P10. The gas supply unit 141 may, by supplying the discharge gas to the flow path 15, swiftly discharge the fluid in the flow path 15 out of the flow path 15 when raising or lowering the target temperature of the temperature control base 14.

The discharge fluid storage unit 142 may store the return fluid discharged out of the flow path 15 by the gas supply unit 141. The discharge fluid storage unit 142 may be connected to the distribution-direction switching unit 152 through the pipe P11. The discharge fluid storage unit 142 may be connected to the first chiller 110 through the pipe P12 and to the second chiller 120 through the pipe P13.

The discharge fluid storage unit 142 may be open to the atmosphere, the discharged discharge gas may be discharged to the atmosphere, and the return fluid and the atmosphere may be stored. The return fluid stored in the discharge fluid storage unit 142 may return to the corresponding chiller (the first chiller 110 or the second chiller 120) depending on the fluid temperature.

The fluid supply control unit 150 may include a temperature control unit 151 and a distribution-direction switching unit 152. The fluid supply control unit 150 may selectively distribute the first fluid from the first chiller 110 and the second fluid from the second chiller 120 to the temperature control base 14.

The temperature control unit 151 may be connected to the distribution-direction switching unit 152 through the pipe P14. The distribution-direction switching unit 152 may be connected to a pipe 16a and a pipe 16b.

The temperature control unit 151 may cool the first fluid to a temperature lower than the target temperature and may heat the second fluid to a temperature higher than the target temperature. The temperature control unit 151 may increase the temperature by about 10° C. or more than the target temperature when the temperature increases, and may decrease the temperature by about-10° C. or more than the target temperature when the temperature decreases. The temperature control unit 151 may adjust the temperature of the temperature adjust target fluid by feedback control.

For example, when the temperature control base 14 continuously supplies the second fluid adjusted to a temperature higher than the target temperature in the second chiller 120 to shorten the time when the temperature increases, an overshoot may occur. After the overshoot occurs, even when the control temperature of the second chiller 120 is controlled to the target temperature, the settling time until stabilization at the target temperature may increase. In contrast, the temperature control unit 151 in the example embodiment may control the temperature of the second fluid to be higher than the target temperature to shorten the temperature-raising time, and may heat and control the second fluid to an appropriate temperature through feedback control without overshooting. Accordingly, the temperature control base 14 may be swiftly controlled to the target temperature without overshooting. Also, the temperature control unit 151 may adjust the temperature of the fluid distributed when the temperature is raised (or lowered) to be higher (or lower) than the target temperature, thereby shortening the temperature control time.

The distribution-direction switching unit 152 may control the distribution direction of the fluid distributed to the temperature control base 14 depending on the fluid temperature. The distribution-direction switching unit 152 may be connected to the first storage unit 131 through the pipe P8. The distribution-direction switching unit 152 may be connected to the second storage unit 132 through the pipe P9. The distribution-direction switching unit 152 may be connected to the discharge fluid storage unit 142 through the pipe P11. The distribution-direction switching unit 152 may be connected to the first chiller 110 through the pipe P3. The distribution-direction switching unit 152 may be connected to the second chiller 120 through the pipe P5.

The distribution-direction switching unit 152 may distribute the first fluid supplied from the first chiller 110 in the second direction from the outer circumferential side of the temperature control base 14 toward the central side. The distribution-direction switching unit 152 may distribute the second fluid supplied from the second chiller 120 in the first direction from the central side of the temperature control base 14 toward the outer circumferential side. Also, the distribution-direction switching unit 152 may distribute the discharge gas supplied from the gas supply unit 141 in the first direction or the second direction.

For example, a conventional plasma processing device uses relatively low-temperature fluid of about −50° C. or less to increase an etching rate and relatively high-temperature fluid of about 50° C. or more to increase the removal efficiency of a deposit removal process, temperature unevenness may occur due to rapid changes in temperature, thereby damaging the electrostatic chuck. To address this issue, extensive research has been conducted focusing on the characteristics of ceramics, which may be a material for the electrostatic chuck 13 described below. It has been found that, by controlling the distribution direction of fluid distributed to a temperature control base 14 in an appropriate direction, damages to the electrostatic chuck 13 may be reduced or prevented even when the fluid having a temperature difference of 100° C. or more may be switched.

In the example embodiment, the electrostatic chuck 13, which is a temperature control target by the first fluid or the second fluid, may be formed of or include ceramics such as Al₂O₃. Ceramics may tend to have extremely low tensile strength with respect to compressive strength. For example, during a low-temperature maintenance operation, the temperature control base 14 may be configured to be in contact with and fixed to the lower body 2b on the surface of the outer circumferential side, and the temperature of the outer circumferential side of the temperature control base 14 may tend to increase due to heat conduction from the lower electrode 12 or the vacuum chamber 10, such that the low-temperature first fluid may be distributed in the second direction. When switching to a temperature raising operation as the subsequent process, and the relatively high-temperature second fluid is distributed in the second direction, which is the same direction as the first fluid, the electrostatic chuck 13 may generate tensile stress in the component because the outer circumferential side has an increased temperature and expands toward the outer circumferential side. Also, because the inner side has a relatively low temperature compared to the outer circumferential side temperature and a relatively small expansion amount compared to the expansion amount of the outer circumferential side, tensile stresses may occur in the component. Accordingly, the electrostatic chuck 13 may be likely to be broken by the thermal stress. In contrast, the temperature control system 100 in the example embodiment may distribute the relatively low-temperature first fluid in the second direction and may distribute the relatively high-temperature second fluid in the first direction, which is opposite to the second direction of the first fluid. Accordingly, the outer circumferential side may have a lower temperature compared to the inner side temperature and a relatively small expansion amount, and the inner side may expand relatively toward the outer circumferential side, such that the electrostatic chuck 13 may generate compressive stress in the component. As described above, the electrostatic chuck 13 formed of or include ceramics may have improved compressive strength, and thus damages due to thermal stress may be reduced or prevented. Also, the electrostatic chuck 13 may correct the unevenness of the temperature distribution of the electrostatic chuck 13 compared to the case in which each fluid is distributed in the same direction.

As described above, the temperature control system 100 may control the distribution direction of the fluid by considering the material characteristics of the electrostatic chuck 13. Accordingly, the temperature control system 100 may control the temperature appropriately while reducing or preventing damages to the electrostatic chuck 13 even in the case in which a rapid temperature change occurs by switching from a low-temperature maintenance operation to a temperature raising operation.

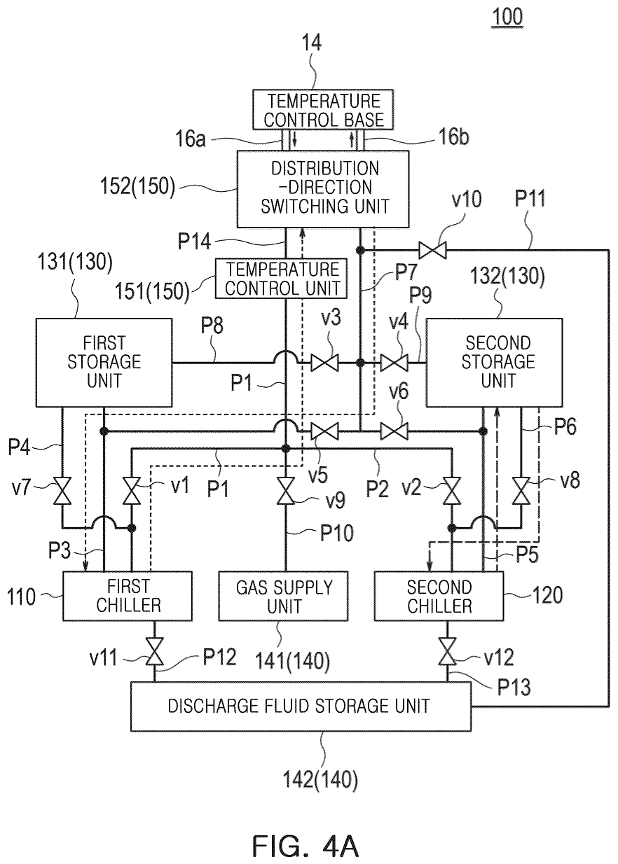

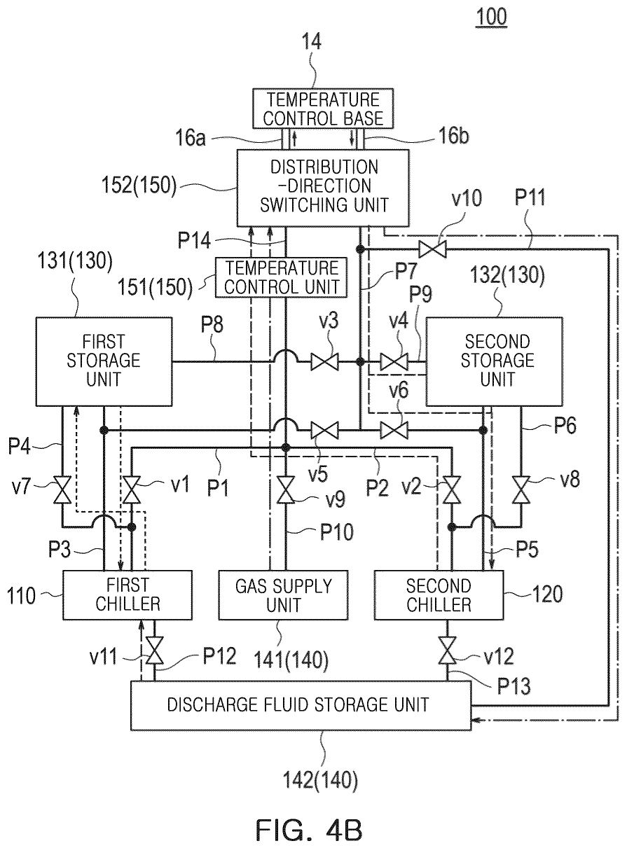

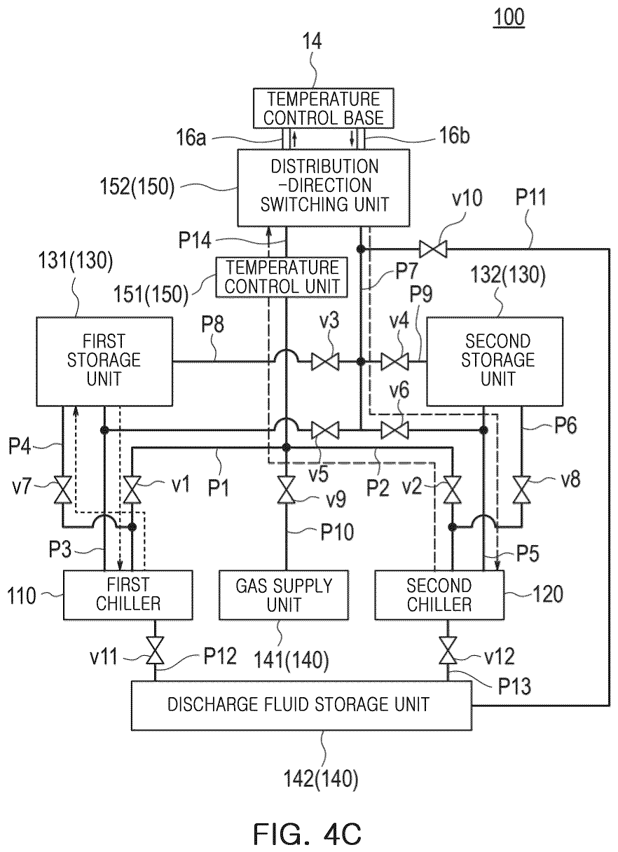

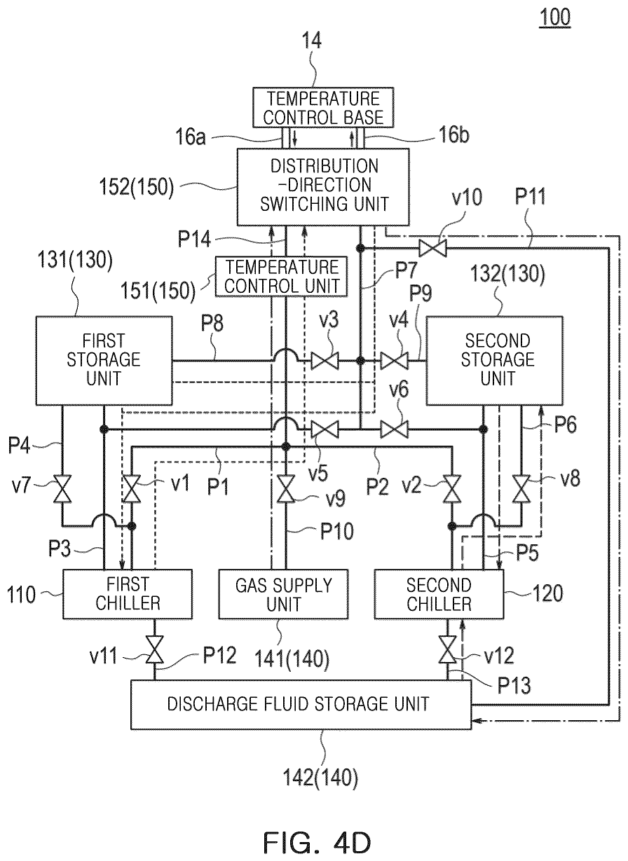

In the description below, the operation of the temperature control system 100 may be described with reference to FIGS. 4A to 4D. In the description below, the flow of fluid in four operations of “low-temperature maintenance operation,” “temperature raising operation,” “high-temperature maintenance operation,” and “temperature lowering operation” may be described. The temperature control system 100 may perform temperature control in the order of low-temperature maintenance operation->temperature raising operation->high-temperature maintenance operation->temperature lowering operation as basic operations.

The low-temperature maintenance operation may be described with reference to FIG. 4A. The low-temperature maintenance operation may be an operation of maintaining a target temperature determined in the range of about −100° C. to about 0° C. The low-temperature maintenance operation may control distribution of fluid by appropriately opening the valves v1, v5, and v8.

In the low-temperature maintenance operation, the temperature control system 100 may control the temperature of the first fluid in the first chiller 110 to the target temperature. Thereafter, the temperature control system 100 may supply the first fluid from the first chiller 110 by opening the valve v1 with respect to the distribution-direction switching unit 152. Because the temperature control base 14 is already at the target temperature, the temperature control unit 151 may perform temperature control for the first fluid only when desired.

The distribution-direction switching unit 152 may distribute the first fluid in the second direction with respect to the flow path 15 of the temperature control base 14. Accordingly, the first fluid may be distributed from the outer circumferential side of the flow path 15 toward the central side.

The first fluid passing through the flow path 15 may return to the first chiller 110 by opening the valve v5. Also, the return fluid stored in the second storage unit 132 may be adjusted to the control temperature of the second chiller 120 by opening the valve v8 and circulating between the second chiller 120 and the second storage unit 132 in preparation for the subsequent temperature raising operation.

As described above, the relatively low-temperature maintenance operation may maintain the temperature control base 14 at the target temperature while circulating the temperature-controlled first fluid by performing the operation at an appropriate timing.

In the description below, the temperature raising operation may be described with reference to FIG. 4B. The temperature raising operation may be an operation of raising the temperature from a relatively low target temperature to a relatively high target temperature after raising the temperature, for example. The temperature raising operation may include controlling the distribution of the fluid by appropriately opening the valves v2, v4, v6-v10, and v11.

In the temperature raising operation, the temperature control system 100 may stop the supply of the first fluid from the first chiller 110 by closing the valve v1. The fluid stored in the second storage unit 132 may be circulated between the first chiller 130 and the second chiller 120 during the low-temperature maintenance operation and adjusted to the control temperature of the second chiller 120. The fluid in the second storage unit 132 may continue to be circulated during the temperature raising operation until the temperature adjusted to the control temperature of the second chiller 120.

Thereafter, the temperature control system 100 may supply the discharge gas from the gas supply unit 141 to the flow path 15 of the temperature control base 14 by opening the valve v9. The flow path 15 supplied with the discharge gas may have the first fluid remaining in the internal region extruded to the outside by the supplied discharge gas. The first fluid discharged from the flow path 15 may return to the discharge fluid storage unit 142 as the return fluid by opening the valve v10. The fluid returned to the discharge fluid storage unit 142 may return to the first chiller 110 by opening the valve v11.

Thereafter, the second chiller 120 may supply the second fluid controlled to the target temperature by opening the valve v2 to the temperature control unit 151. The temperature control unit 151 may control the temperature of the second fluid flowing in while performing feedback control, and may supply the fluid to the distribution-direction switching unit 152 through the pipe P14.

The distribution-direction switching unit 152 may distribute the second fluid in the first direction of the flow path 15. Accordingly, the second fluid may be distributed from the central side of the flow path 15 toward the outer circumferential side.

The second fluid passing through the flow path 15 may return to the second storage unit 132 by opening the valve v4. The second storage unit 132 may return the second fluid, which is the return fluid, to the second chiller 120 after the temperature thereof is adjusted to the same temperature as the control temperature of the second chiller 120. Also, when the temperature of the return fluid becomes the same as the control temperature of the second chiller 120, the valve v6 may be opened, and the distribution direction may be switched to the pipe P5, which becomes a bypass path, such that the return fluid may directly return to the second chiller 120. The fluid stored in the first storage unit 131 may be adjusted to the control temperature of the first chiller 110 by opening the valve v7 and being circulated between the first chiller 110 and the first storage unit 131 in preparation for the subsequent temperature lowering operation.

As described above, the temperature raising operation may, by performing the operation at an appropriate timing, raise the temperature control base 14 to the target temperature by circulating the temperature-controlled second fluid.

In the description below, the high-temperature maintenance operation may be described with reference to FIG. 4C. The high-temperature maintenance operation may be an operation of maintaining the target temperature determined in the range of about 40° C. to about 200° C. The high-temperature maintenance operation may perform distribution control over the fluid by appropriately opening the valves v2, v6, and v7.

In the high-temperature maintenance operation, the temperature control system 100 may control the temperature of the second fluid in the second chiller 120 to the target temperature. Thereafter, the temperature control system 100 may supply the second fluid from the second chiller 120 by opening the valve v2 to the distribution-direction switching unit 152. Because the temperature control base 14 is already at the target temperature, the temperature control unit 151 may perform temperature control for the second fluid only when desired.

The distribution-direction switching unit 152 may distribute the second fluid in the first direction with respect to the flow path 15 of the temperature control base 14. Accordingly, the second fluid may be distributed from the central side of the flow path 15 toward the outer circumferential side.

The second fluid passing through the flow path 15 may return to the second chiller 120 by opening the valve v6. Also, the fluid stored in the first storage unit 131 may be adjusted to the control temperature of the first chiller 110 by opening the valve v7 and being circulated between the first chiller 110 and the first storage unit 131 in preparation for the subsequent temperature lowering operation.

As described above, the high-temperature maintenance operation may, by performing the operation at an appropriate timing, maintain the temperature control base 14 at the target temperature by circulating the temperature-controlled second fluid.

The temperature lowering operation may be described with reference to FIG. 4D. The temperature lowering operation may be an operation of lowering the temperature from a relatively high target temperature before the temperature is lowered to a relatively low target temperature after the temperature is lowered. The temperature lowering operation may perform distribution control over the fluid by appropriately opening valves v1, v3, v5, v7-v10, and v12.

In the temperature lowering operation, the temperature control system 100 may stop supply of the second fluid from the second chiller 120 by closing the valve v2. The fluid stored in the first storage unit 131 may be circulated between the first chiller 110 and the first storage unit 131 and may be adjusted to the control temperature of the first chiller 110 during a high-temperature maintenance operation. The fluid in the first storage unit 131 may continue to be circulated during the temperature lowering operation until the fluid is adjusted to the control temperature of the first chiller 110.

Thereafter, the temperature control system 100 may supply a discharge gas from the gas supply unit 141 to the flow path 15 of the temperature control base 14 by opening the valve v9. Through the flow path 15 supplied with the discharge gas, the first fluid remaining therein may be pushed out to the outside by the supplied discharge gas. The second fluid discharged from the flow path 15 may return to the discharge fluid storage unit 142 as return fluid by opening the valve v10. The fluid returned to the discharge fluid storage unit 142 may return to the second chiller 120 by opening the valve v12.

Thereafter, the first chiller 110 may supply the first fluid controlled to the target temperature by opening the valve v1 to the temperature control unit 151. The temperature control unit 151 may control the temperature of the first fluid flowing in while performing feedback control, and supply the fluid to the distribution-direction switching unit 152 through the pipe P14.

The distribution-direction switching unit 152 may distribute the second fluid in the second direction of the flow path 15. Accordingly, the second fluid may be distributed from the outer circumferential side of the flow path 15 toward the central side.

The first fluid passing through the flow path 15 may return to the first storage unit 131 by opening the valve v3. The first storage unit 131 may adjust the first fluid, which is the return fluid, to a temperature equal to the control temperature of the first chiller 110 and may return the fluid to the first chiller 110. Also, the return fluid may directly return to the first chiller 110 by opening the valve v5 and switching the distribution direction of the return fluid to the pipe P3, which becomes a bypass path, when the temperature becomes equal to the control temperature of the first chiller 110. The fluid stored in the second storage unit 132 may be adjusted to the control temperature of the second chiller 120 by opening the valve v8 and circulating between the second chiller 120 and the second storage unit 132 in preparation for the subsequent temperature raising operation.

As described above, by performing the temperature lowering operation at an appropriate timing, the temperature-controlled first fluid may be circulated and the temperature control base 14 may be cooled to the target temperature.

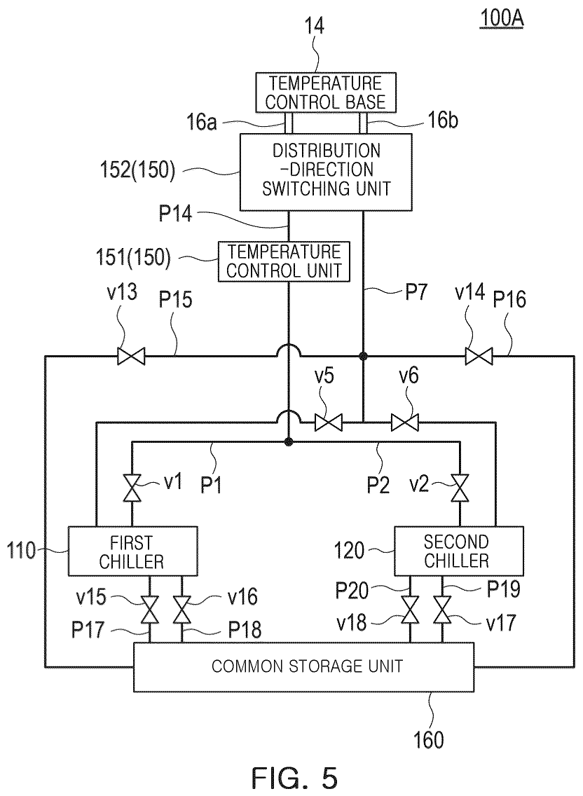

FIG. 5 illustrates a block diagram illustrating the temperature control system 100A according to an example embodiment. The same reference numerals are used to denote the same elements as in the above-described example embodiments, and thus, repeated descriptions thereof are omitted. For the descriptions not specifically mentioned, the same descriptions as in the above-described example embodiments may be applied.

The temperature control system 100A may be different from the above-described example in that the temperature control system 100A may include a common storage unit 160 instead of the first storage unit 131 and the second storage unit 132 as illustrated in FIG. 5.

The common storage unit 160 may store a fluid having a temperature different from the control temperature of the first chiller 110 or the second chiller 120 by passing through the flow path 15 when the temperature is raised or lowered, and may return fluid close to the control temperature to the first chiller 110 or the second chiller 120. The common storage unit 160 may supply the return fluid controlled to the control temperature of the first chiller 110 as first fluid to the first chiller 110 during the temperature lowering operation. The common storage unit 160 may supply the return fluid controlled to the control temperature of the second chiller 120 as the second fluid to the second chiller 120 during the temperature raising operation. The common storage unit 160 may function as a buffer element to block or prevent the first fluid supplied from the first chiller 110 or the second fluid supplied from the second chiller 120 from changing from the control temperature due to the fluid passing through the flow path 15 and having a temperature different from the control temperature.

The common storage unit 160 may be connected to the first chiller 110 through pipes P17 and P18 and may circulate the fluid. The common storage unit 160 may be connected to the second chiller 120 through pipes P19 and P20 and may circulate fluid. The common storage unit 160 may be connected to the distribution-direction switching unit 152 through a pipe P15 including a valve v13 disposed therein and a pipe P16 including a valve v14 disposed therein, and may allow return fluid to flow in from the temperature control base 14.

When a relatively high temperature is maintained, the common storage unit 160 may allow the stored return fluid to circulate between the first chiller 110 and the common storage unit 160 through a pipe P17 including a valve v15 disposed therein and a pipe P18 including a valve v16 disposed therein so as to reach the control temperature of the first chiller 110. When a relatively low temperature is maintained, the common storage unit 160 may allow the stored return fluid to circulate between the second chiller 120 and the common storage unit 160 through a pipe P19 including a valve v17 disposed therein and a pipe P20 including a valve v18 disposed therein so as to reach the control temperature of the second chiller 120. Accordingly, the common storage unit 160 may adjust the stored fluid to the control temperature of the first chiller 110 or the second chiller 120 in preparation for the subsequent temperature raising operation or temperature lowering operation.

The common storage unit 160 may be configured to store the first fluid and the second fluid, and may be configured as a storage tank or a chiller having a temperature control function.

The temperature control unit 151 may control the fluid from the first chiller 110 and the second chiller 120 by feedback control and may raise or lower the temperature further than the target temperature. Accordingly, the temperature control base 14 may shorten the temperature control time to reach the target temperature because the first fluid or the second fluid, the temperature of which is raised or lowered further than the target temperature, is distributed.

As described above, the temperature control system 100A may control the return fluid to the first chiller 110 or the second chiller 120 to the target temperature in advance in order to allow the temperature of the return fluid to the first chiller 110 or the second chiller 120 to be almost equal to the respective chiller control temperatures when switching to fluid having different temperatures when the temperature is raised or lowered. Accordingly, in the temperature control system 100A, the temperature fluctuation due to the return fluid of the first fluid or the second fluid when the temperature is raised or lowered may be reduced or prevented, and the temperature control system 100A may control the temperature more swiftly and efficiently. Also, the temperature control system 100A may store the return fluid from the temperature control base 14 in the common storage unit 160, may adjust the fluid to the same control temperature as the first chiller 110 or the second chiller 120, and may return the fluid to the corresponding chiller. Accordingly, the temperature fluctuation of the first fluid in the first chiller 110 or the second fluid in the second chiller 120 may be suppressed or prevented.

The above-described temperature control system 100A does not include the fluid discharge unit 140 as illustrated in FIG. 5, but may include the fluid discharge unit 140. In this case, the fluid discharge unit 140 may swiftly discharge the fluid in the flow path 15 when the temperature is raised or lowered, during which the temperature raising operation or the temperature lowering operation is performed.

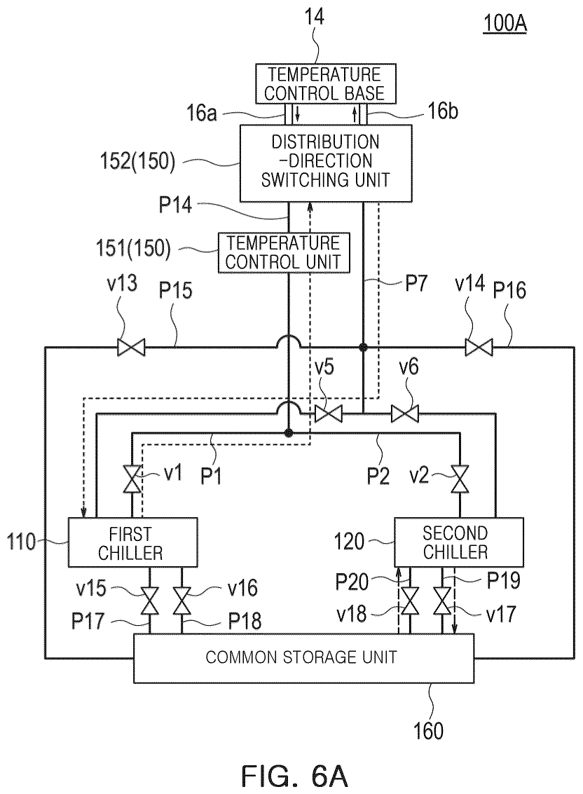

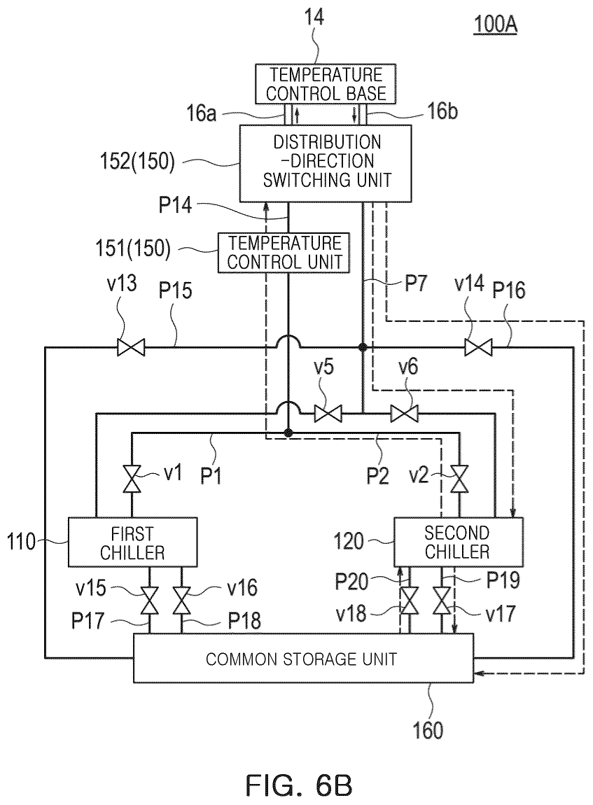

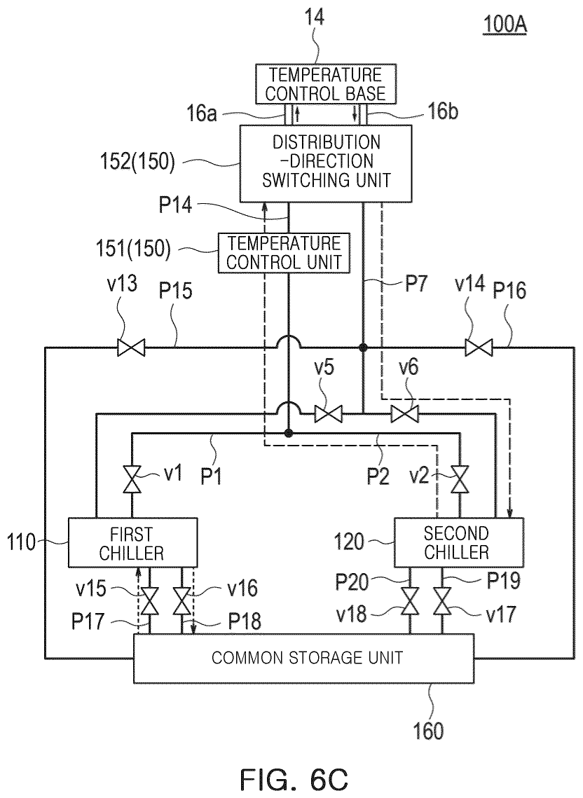

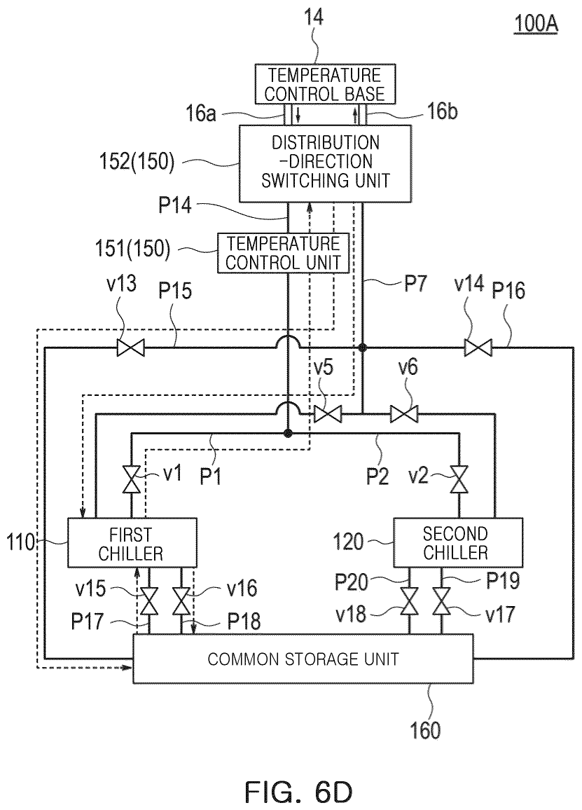

In the description below, the operation of the temperature control system 100A may be described with reference to FIGS. 6A to 6D. Hereinafter, the flow of fluid in four operations, “low-temperature maintenance operation,” “temperature raising operation,” “high-temperature maintenance operation,” and “temperature lowering operation,” may be described. The temperature control system 100A may perform temperature control in the order of low-temperature maintenance operation->temperature raising operation->high-temperature maintenance operation->temperature lowering operation as basic operations.

The low-temperature maintenance operation may be described with reference to FIG. 6A. The low-temperature maintenance operation may control distribution over fluid by appropriately opening valves v1, v5, v17, and v18.

In the low-temperature maintenance operation, the temperature control system 100A may control the temperature of the first fluid in the first chiller 110 to the target temperature. Thereafter, the temperature control system 100A may supply the first fluid from the first chiller 110 by opening the valve v1 with respect to the distribution-direction switching unit 152.

The distribution-direction switching unit 152 may distribute the first fluid in the second direction with respect to the flow path 15 of the temperature control base 14. Accordingly, the first fluid may be distributed from the outer circumferential side of the flow path 15 toward the central side.

The first fluid passing through the flow path 15 may return to the first chiller 110 by opening the valve v5. Also, the fluid stored in the common storage unit 160 may be adjusted to the control temperature of the second chiller 120 by opening the valves v17 and v18 and circulating between the second chiller 120 and the common storage unit 160 in preparation for the subsequent temperature raising operation.

As described above, by performing the low-temperature maintenance operation at an appropriate timing, the temperature control base 14 may be maintained at the target temperature while the temperature-controlled first fluid is circulated.

The temperature raising operation may be described with reference to FIG. 6B. The temperature raising operation may perform distribution control over the fluid by appropriately opening valves v2, v6, v14, and v18.

In the temperature raising operation, the temperature control system 100A may stop the supply of the first fluid from the first chiller 110 by closing the valve v1.

Thereafter, the temperature control system 100A may supply the second chiller 120 by opening the valve v2 for the temperature control unit 151. The temperature control unit 151 may increase the temperature of the second fluid flowing in by feedback control to a temperature higher than the target temperature and may supply the second fluid to the distribution-direction switching unit 152 through the pipe P14.

The distribution-direction switching unit 152 may distribute the second fluid in the first direction of the flow path 15. Accordingly, the second fluid may be distributed from the central side of the flow path 15 toward the outer circumferential side.

The second fluid passing through the flow path 15 may return to the common storage unit 160 by opening the valve v14. The temperature control system 100A may supply the fluid stored in the common storage unit 160 to the second chiller 120 until the temperature of the second fluid approaches the temperature of the common storage unit 160.

The temperature control system 100A may stop the supply of the fluid from the common storage unit 160 when the temperature of the second fluid returning to the common storage unit 160 approaches the control temperature of the second chiller 120. The return fluid may directly return to the second chiller 120 by opening the valve v6 and switching the distribution direction of the return fluid to the pipe P7, which becomes a bypass path.

As described above, by performing the temperature raising operation at an appropriate timing, the temperature of the temperature control base 14 may be raised to the target temperature while the temperature-controlled second fluid is circulated.

The high-temperature maintenance operation may be described with reference to FIG. 6C. The high-temperature maintenance operation may control distribution over fluid by appropriately opening valves v2, v6, v15, and v16.

In the high-temperature maintenance operation, the temperature control system 100A may control the temperature of the second fluid in the second chiller 120 to the target temperature. Thereafter, the temperature control system 100A may supply the second fluid from the second chiller 120 by opening the valve v2 to the distribution-direction switching unit 152. Because the temperature control base 14 is already at the target temperature, the temperature control unit 151 may perform the temperature control for the second fluid only when desired.

The distribution-direction switching unit 152 may distribute the second fluid in the first direction with respect to the flow path 15 of the temperature control base 14. Accordingly, the second fluid may be distributed from the central side to the outer circumferential side of the flow path 15.

The second fluid passing through the flow path 15 may return to the second chiller 120 by opening the valve v6. Also, the fluid stored in the common storage unit 160 may be circulated between the first chiller 110 and the common storage unit 160 and may be adjusted to the control temperature of the first chiller 110 in preparation for the subsequent temperature lowering operation.

As described above, by performing the high-temperature maintenance operation at an appropriate timing, the temperature of the temperature control base 14 may be maintained at the target temperature while the temperature-controlled second fluid is circulated.

The temperature lowering operation may be described with reference to FIG. 6d. The temperature lowering operation may perform distribution control over the fluid by appropriately opening valves v1, v5, v13, and v15

In the temperature lowering operation, the temperature control system 100A may stop the supply of the second fluid from the second chiller 120 by closing the valve v2.

Thereafter, the temperature control system 100A may supply the first chiller 110 by opening the valve v1 for the temperature control unit 151. The temperature control unit 151 may cool the first fluid flowing in to a temperature lower than the target temperature, and may supply the first fluid to the distribution-direction switching unit 152 through the pipe P14.

The distribution-direction switching unit 152 may distribute the first fluid in the second direction of the flow path 15. Accordingly, the first fluid may be distributed from the outer circumferential side of the flow path 15 toward the central side.

The first fluid passing through the flow path 15 may return to the common storage unit 160 by opening the valve v13. The temperature control system 100A may supply the fluid stored in the common storage unit 160 to the first chiller 110 until the temperature of the first fluid approaches the temperature of the common storage unit 160.

The temperature control system 100A may stop the supply of the fluid from the common storage unit 160 when the temperature of the first fluid returning to the common storage unit 160 approaches the control temperature of the first chiller 110. The return fluid may directly return to the first chiller 110 by opening valve v5 and switching the distribution direction pf the return fluid to pipe P7, which becomes a bypass path.

As described above, by performing the temperature lowering operation at an appropriate timing, the temperature control base 14 may be lowered to the target temperature while the temperature-controlled first fluid is circulated.

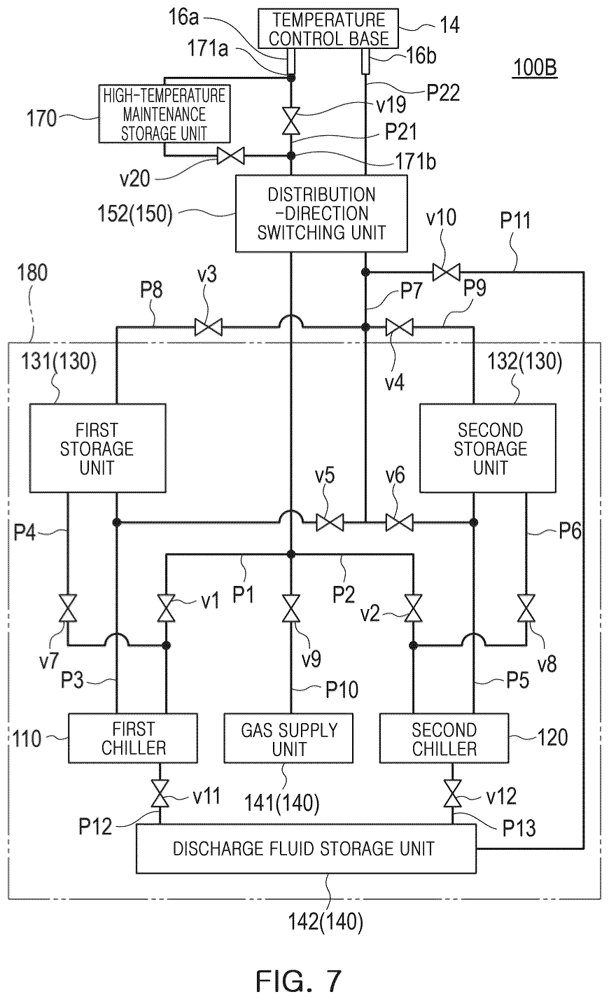

FIG. 7 is a block diagram illustrating a temperature control system 100B according to the third example embodiment. The same reference numerals are used to denote the same elements as in the above-described example embodiments, and thus, repeated descriptions thereof are omitted. For the descriptions not specifically mentioned, the same descriptions as in the above-described example embodiments may be applied.

The temperature control system 100B may be different from the above-described example embodiments in that the temperature control system 100B may include a high-temperature maintenance storage unit (or alternatively referred to as a high-temperature storage unit) 170 as illustrated in FIG. 7. For ease of description, the temperature control fluid distributed in the temperature control system 100B may be referred to as “first fluid” for the fluid controlled at a relatively low temperature in the first chiller 110, “second fluid” for the fluid controlled at a relatively high temperature in the second chiller 120, and “third fluid” for the fluid supplied from the high-temperature maintenance storage unit 170. However, the fluids may merely have different temperatures, and may be a single type of fluid distributed in the system.

The temperature control system 100B may include a high-temperature maintenance storage unit 170 and a temperature elevation control unit 180 as illustrated in FIG. 7. The temperature control system 100B may dispose the high-temperature maintenance storage unit 170 between the temperature control base 14 and the distribution-direction switching unit 152 as illustrated in FIG. 7. Although not illustrated, the high-temperature maintenance storage unit 170 may be disposed on the downstream side of the distribution-direction switching unit 152. The temperature control base 14 and the distribution-direction switching unit 152 may be connected to each other by pipes P21 and P22. A pipe 21 may include a valve v19 disposed therein. A valve v20 may be disposed on the downstream side of the fluid distribution port 171b of the high-temperature maintenance storage unit 170.

The high-temperature maintenance storage unit 170 may include fluid distribution ports 171a and 171b disposed between the temperature control base 14 and the temperature elevation control unit 180, and may supply a third fluid adjusted to a temperature higher than the target temperature (+10° C. or more) from the fluid distribution port 171a. The fluid distribution port 171a may be connected to a pipe P1 or a pipe 16a. The fluid distribution port 171b may be connected to a pipe P1 or a pipe P21. The third fluid may be distributed from the central side of the flow path 15 toward the outer circumferential side.

Also, the high-temperature maintenance storage unit 170 may be disposed in the vicinity (in 1 m) of the temperature control base 14 in order to enhance temperature elevation responsiveness. Accordingly, the temperature control system 100B may supply the third fluid supplied from the high-temperature maintenance storage unit 170 to the temperature control base 14 while suppressing the temperature decrease during distribution and maintaining the relatively high temperature. Accordingly, the temperature control system 100B may shorten the temperature control time.

In the temperature raising operation, the high-temperature maintenance storage unit 170 may stop the supply of fluid when the supply of the third fluid for the storage capacity is finished or when the third fluid of the desired (or alternatively, predetermined) amount is supplied. The second chiller 120 may start the supply of the second fluid when the supply of the third fluid from the high-temperature maintenance storage unit 170 is stopped.

The temperature elevation control unit 180 may include the first chiller 110, the second chiller 120, the storage unit 130, and the discharge fluid storage unit 140. The temperature elevation control unit 180 may be positioned on the upstream side of the temperature control base 14 and may control the temperature by supplying the fluid controlled to a desired (or alternatively, predetermined) temperature to the temperature control base 14.

The temperature control system 100B does not include the temperature control unit 151 as illustrated in FIGS. 5 and 6A-6D, but may include the temperature control unit 151 therein. In this case, the temperature control unit 151 may raise or lower the temperatures of the first fluid, the second fluid, and/or the third fluid to a desired temperature during a temperature raising operation or a temperature lowering operation. Also, the temperature control system 100B may be configured to further include a common storage unit 160 and to store the return fluid from the temperature control base 14, similarly to the temperature control system 100A in the above example embodiments.

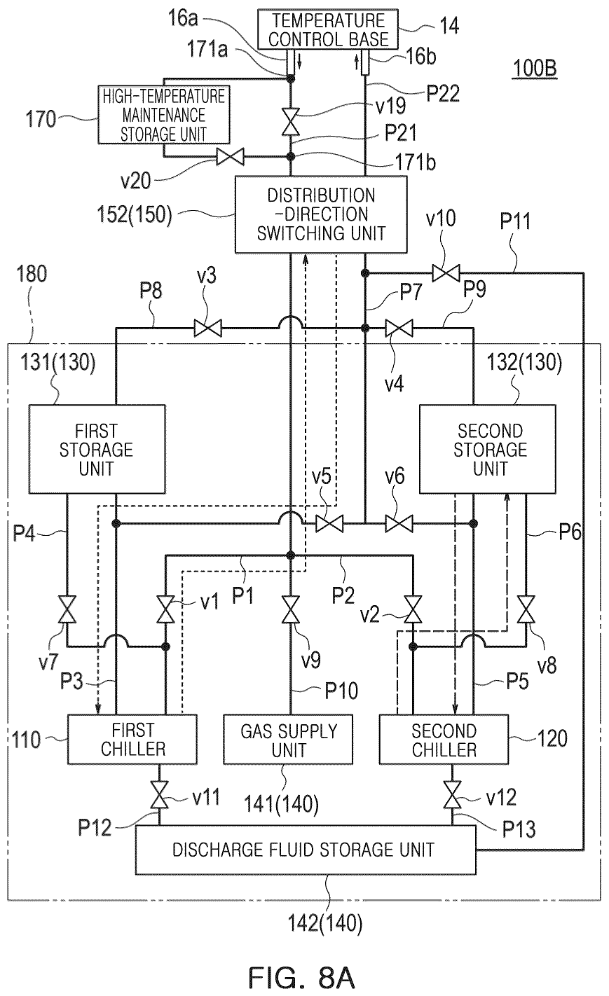

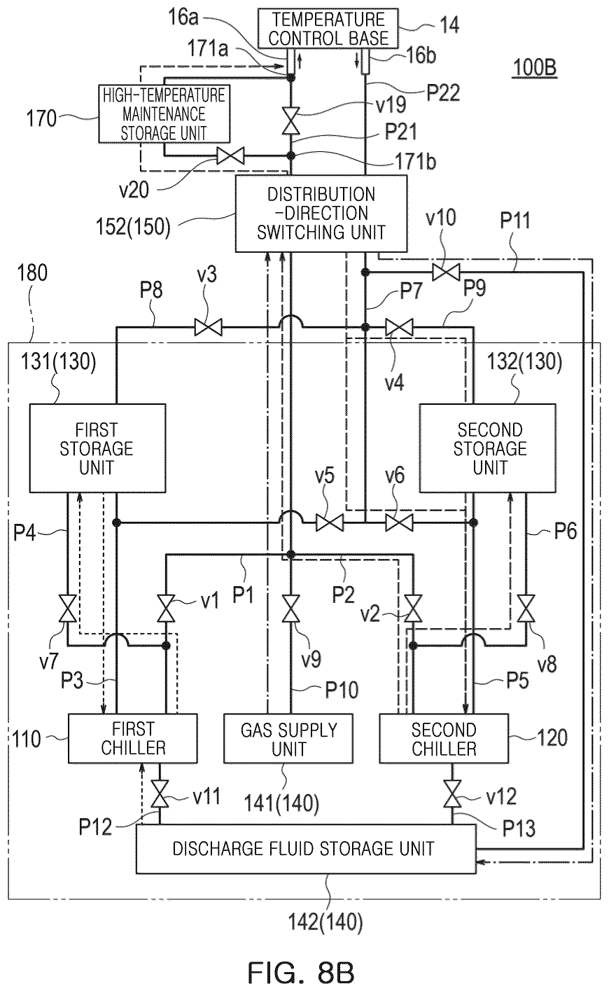

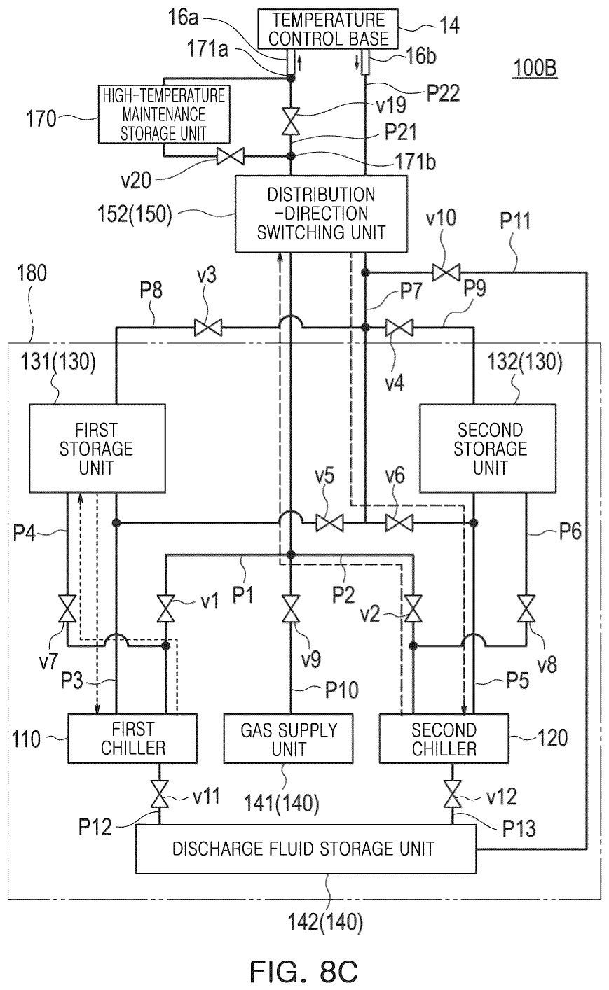

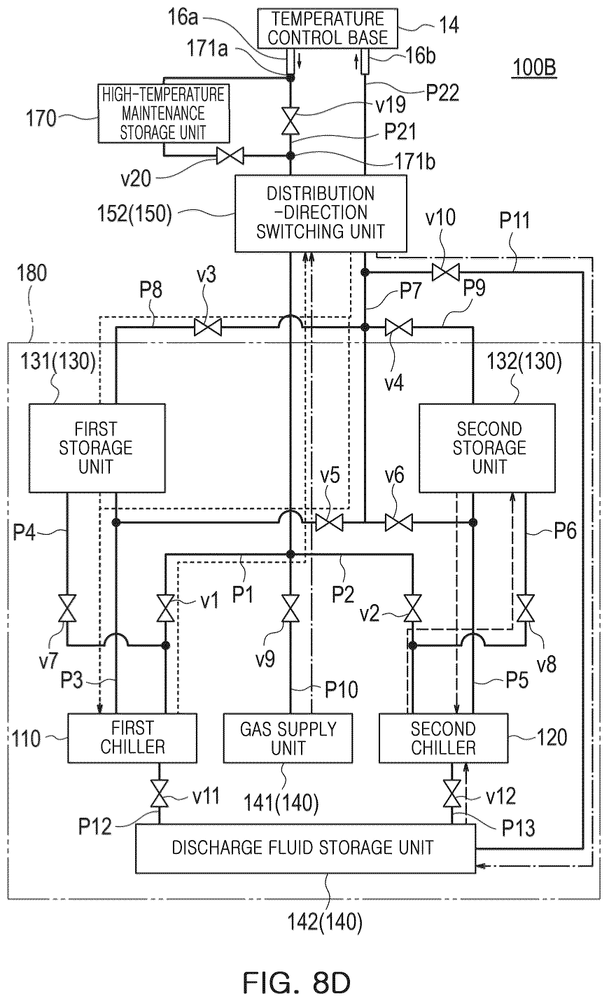

In the description below, the operation of the temperature control system 100B may be described with reference to FIGS. 8A to 8D. In the description below, the flow of fluid in four operations of “low-temperature maintenance operation,” “temperature raising operation,” “high-temperature maintenance operation,” and “temperature lowering operation” may be described. Here, the description may be made based on the system configuration illustrated in FIG. 7. The temperature control system 100B may perform temperature control in the order of low-temperature maintenance operation->temperature raising operation->high-temperature maintenance operation->temperature lowering operation as basic operations.

The low-temperature maintenance operation may be described with reference to FIG. 8A. The low-temperature maintenance operation may perform distribution of fluid control by appropriately opening valves v1, v5, v8, and v19.

In the low-temperature maintenance operation, the temperature control system 100B may control the temperature of the first fluid in the first chiller 110 to the target temperature. Thereafter, the temperature control system 100B may supply the first fluid from the first chiller 110 by opening the valve v1 with respect to the distribution-direction switching unit 152.

The distribution-direction switching unit 152 may distribute the first fluid in the second direction through pipe P22 with respect to the flow path 15 of the temperature control base 14. Accordingly, the first fluid may be distributed from the outer circumferential side of the flow path 15 toward the central side.

The first fluid passing through the flow path 15 may pass through the pipe P21 and the distribution-direction switching unit 152 by opening the valve v19, and may return to the first chiller 110 by opening the valve v5. The fluid stored in the second storage unit 132 may be adjusted to the control temperature of the second chiller 120 by opening the valve v8 and circulating between the second chiller 120 and the second storage unit 132 in preparation for the subsequent temperature raising operation.

As described above, by performing the low-temperature maintenance operation at an appropriate timing, the temperature control base 14 may be maintained at the target temperature while the temperature-controlled first fluid is circulated.

The temperature raising operation may be described with reference to FIG. 8B. The temperature raising operation may perform distribution control over the fluid by appropriately opening valves v2, v4, v6-v11, v19, and v20.

In the temperature raising operation, the temperature control system 100B may stop the supply of the first fluid from the first chiller 110 by closing the valve v1. The fluid stored in the second storage unit 132 may be circulated between the second chiller 120 and the second storage unit 132 during the low-temperature maintenance operation and may be adjusted to the control temperature of the second chiller 120. The fluid in the second storage unit 132 may continue to be circulated during the temperature raising operation until the fluid is adjusted to the control temperature of the second chiller 120.

Thereafter, the temperature control system 100B may open the valves v9 and v19 for the flow path 15 connected to the temperature control base 14 and may supply the discharge gas from the gas supply unit 141. Through the flow path 15 supplied with the discharge gas, the first fluid remaining therein may be pushed out to the outside by the supplied discharge gas. The first fluid discharged from the flow path 15 may return to the discharge fluid storage unit 142 as return fluid by opening the valve v10 after passing through the pipe P22 and the distribution-direction switching unit 152. The fluid returned to the discharge fluid storage unit 142 may return to the first chiller 110 by opening the valve v11.

Thereafter, the high-temperature maintenance storage unit 170 may supply the third fluid, of which the temperature is controlled to a temperature higher than the target temperature with respect to the temperature control base 14, from the fluid distribution port 171a by closing the valve v19 and opening the valve v20. The third fluid may distribute the second fluid in the first direction of the flow path 15. Accordingly, the second fluid may be distributed from the central side of the flow path 15 toward the outer circumferential side. The method of distributing the third fluid of the high-temperature maintenance storage unit 170 may include an active supply function, or may be a passive function of pushing the third fluid into the second fluid as a sealed container. The valves v19 and v20 may be appropriately opened and closed according to the functions thereof.

Thereafter, the temperature control system 100B may open the valve v2 when the supply from the high-temperature maintenance storage unit 170 is stopped, and may supply the second fluid from the second chiller 120 to the distribution-direction switching unit 152 by controlling the temperature thereof to a target temperature. The distribution-direction switching unit 152 may distribute the second fluid in the first direction of the flow path 15 by opening the valve v19. Accordingly, the second fluid may be distributed from the central side of the flow path 15 toward the outer circumferential side.

The second fluid passing through flow path 15 may pass through the pipe P22 and the distribution-direction switching unit 152 and may return to the second storage unit 132 by opening the valve v4. The second storage unit 132 may return the second fluid, which is the return fluid, to the second chiller 120 after adjusting the temperature thereof to the same temperature as the control temperature of the second chiller 120. Also, when the temperature of the return fluid becomes the same as the control temperature of the second chiller 120, the valve v6 may be opened, and the distribution direction may be switched to the pipe P5, which becomes a bypass path, such that the return fluid may directly return to the second chiller 120. During the temperature raising operation, the fluid stored in the first storage unit 131 may be adjusted to the control temperature of the first chiller 110 by opening the valve v7 and circulating between the first chiller 110 and the first storage unit 131 in preparation for the subsequent temperature lowering operation.

As described above, by performing the temperature raising operation at an appropriate timing, the temperature control base 14 may be raised to the target temperature while the temperature-controlled second fluid is circulated.

The high-temperature maintenance operation may be described with reference to FIG. 8C. The high-temperature maintenance operation may perform distribution control over the fluid by appropriately opening valves v2, v6, v7, and v19.

In the high-temperature maintenance operation, the temperature control system 100B may control the temperature of the second fluid in the second chiller 120 to the target temperature. Thereafter, the temperature control system 100B may supply the second fluid from the second chiller 120 to the distribution-direction switching unit 152 by opening the valve v2.

The distribution-direction switching unit 152 may distribute the second fluid in the first direction by opening the valve v19 with respect to the flow path 15 of the temperature control base 14. Accordingly, the second fluid may be distributed from the central side of the flow path 15 toward the outer circumferential side.

The second fluid passing through the flow path 15 may pass through the pipe P22 and the distribution-direction switching unit 152 and may return to the second chiller 120 by opening the valve v6. The fluid stored in the first storage unit 131 during the high-temperature maintenance operation may be adjusted to the control temperature of the first chiller 110 by opening the valve v7 and circulating between the first chiller 110 and the first storage unit 131 in preparation for the subsequent temperature lowering operation.

As described above, by performing the high-temperature maintenance operation at an appropriate timing, the temperature control base 14 may be maintained at the target temperature while the temperature-controlled second fluid is circulated.

The temperature lowering operation may be described with reference to FIG. 8D. The temperature lowering operation may perform distribution control over the fluid by appropriately opening valves v1, v3, v5, v8, v9, v10, v12, and v19.

In the temperature lowering operation, the temperature control system 100B may stop the supply of the second fluid from the second chiller 120 by closing the valve v2. The fluid stored in the first storage unit 131 may be adjusted to the control temperature of the first chiller 110 by circulating between the first chiller 110 and the first storage unit 131 during the high-temperature maintenance operation. The fluid in the first storage unit 131 may continue to circulate during the temperature lowering operation until the fluid is adjusted to the control temperature of the first chiller 110.

Thereafter, the temperature control system 100B may to supply the discharge gas from the gas supply unit 141 to the flow path 15 of the temperature control base 14 by opening the valve v9. Through the flow path 15 supplied with the discharge gas, the second fluid remaining therein may be pushed out to the outside by the supplied discharge gas. The second fluid discharged from the flow path 15 may return to the discharge fluid storage unit 142 as return fluid by opening the valve v10. The fluid returned to the discharge fluid storage unit 142 may return to the second chiller 120 by opening the valve v12.

Thereafter, the temperature control system 100B may supply the first fluid from the first chiller 110 by opening the valve v1 and controlling the distribution-direction switching unit 152 to the target temperature. The distribution-direction switching unit 152 may distribute the first fluid in the second direction of the flow path 15 through the pipe P22. Accordingly, the first fluid may be distributed from the outer circumferential side of the flow path 15 toward the central side.

The first fluid passing through the flow path 15 may return to the first storage unit 131 by opening the valve v3. The first storage unit 131 may adjust the first fluid, which is the return fluid, to a temperature equal to the control temperature of the first chiller 110 and may return the fluid to the first chiller 110. Also, when the temperature becomes equal to the control temperature of the first chiller 110, the return fluid may directly return to the first chiller 110 by opening the valve v5 and switching to the pipe P3, the distribution direction of which becomes a bypass path. During the temperature lowering operation, the fluid stored in the second storage unit 132 may be adjusted to the control temperature of the second chiller 120 by opening the valve v8 and circulating between the second chiller 120 and the second storage unit 132 in preparation for the subsequent temperature raising operation.

As described above, by performing the temperature lowering operation at an appropriate timing, the temperature of the temperature control base 14 may be lowered to the target temperature while the temperature-controlled first fluid is circulated.

As described above, the temperature control system 100 according to the example embodiment may include a maintenance plate (electrostatic chuck 13) connected to a plasma processing device 1 for plasma etching a work W in a vacuum chamber 10 and maintaining the work W mounted on a mounting surface, a temperature control base 14 bonded to the maintenance plate and including a flow path 15 formed therein, which allows fluid to be distributed such that the maintenance plate reaches the target temperature, a lower body 2b for maintaining the temperature control base 14 in the vacuum chamber 10, a first chiller 110 supplying first fluid controlled to a desired (or alternatively, predetermined) temperature, a second chiller 120 supplying second fluid controlled at a temperature different from the temperature controlled in the first chiller 110, and a fluid supply control unit 150 selectively distributing at least one of the first fluid from the first chiller 110 or the second fluid from the second chiller 120 to the temperature control base 14. The fluid supply control unit 150 may include a temperature control unit 151 for heating or cooling the first fluid or the second fluid flowing into the temperature control base 14 to reach a target temperature, and a distribution-direction switching unit 152 for controlling the distribution direction of each fluid. The distribution-direction switching unit 152 may distribute the second fluid in the first direction from the central side of the temperature control base 14 toward the outer circumferential side of the temperature control base 14 when the temperature increases, and may distribute the first fluid in the second direction from the outer circumferential side of the temperature control base 14 toward the central side of the temperature control base 14 when the temperature decreases.

Accordingly, even when the temperature control system 100 distributes a fluid having a temperature difference of about 100° C. or more when moving from a cryogenic environment to a process for removing deposits, for example, uneven in the temperature distribution of the maintenance plate (electrostatic chuck 13) when the temperature increases may be reduced or prevented, thereby reducing or preventing damages due to thermal stress accompanying the temperature change. Also, the temperature control system 100 may adjust the temperature of the first fluid or second fluid distributed to the flow path 15 to a temperature higher (or lower) than the target temperature by the temperature control unit 151. Accordingly, the temperature control system 100 may shorten the temperature control time for the desired target temperature.

The effects of the present disclosure may be described using an example embodiments and a comparative example as below. However, the technical scope of the present disclosure is not limited to the simulation examples below.

In the following example embodiments, a simulation was performed to calculate the temperature distribution and distribution of stress on the mounting surface of a ceramic electrostatic chuck.

The electrostatic chuck used herein was formed of Al₂O₃. The temperature control base bonded to the electrostatic chuck was formed of titanium (Ti). The flow path formed in the temperature control base was formed in a vortex shape by a single-stroke method from the central side to the outer circumferential side as illustrated in FIG. 3A. The distributed fluid used herein was Galden®, which is a fluorine-based liquid.

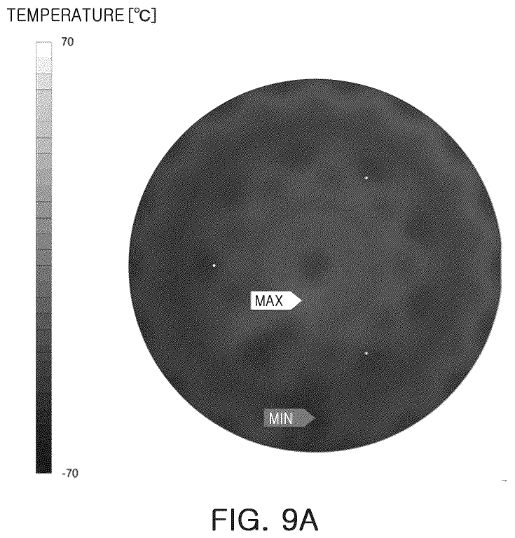

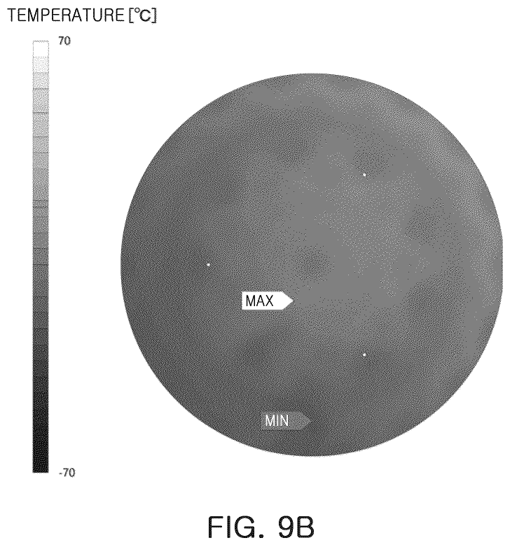

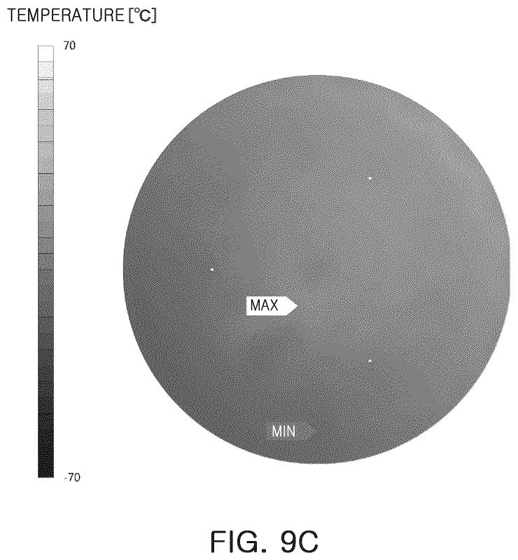

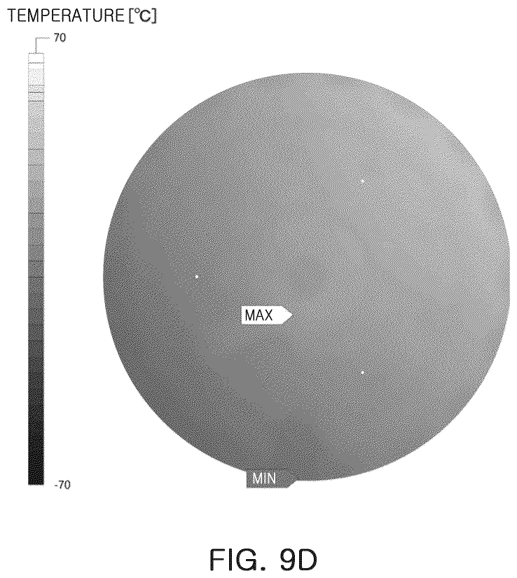

FIGS. 9A-9D are diagrams illustrating simulation results of the example embodiment and shows that at relatively low temperatures, relatively low-temperature fluid (first fluid) was distributed in the second direction from the outer circumferential side of the flow path toward the central side of the flow path, and at relatively high temperatures, relatively high-temperature fluid (second fluid) was distributed in the first direction from the central side of the flow path toward the outer circumferential side of the flow path. That is, in the simulation example, the distribution direction of the first fluid and the distribution direction of the second fluid were opposite to each other. The distribution speed of each fluid was configured to be constant.

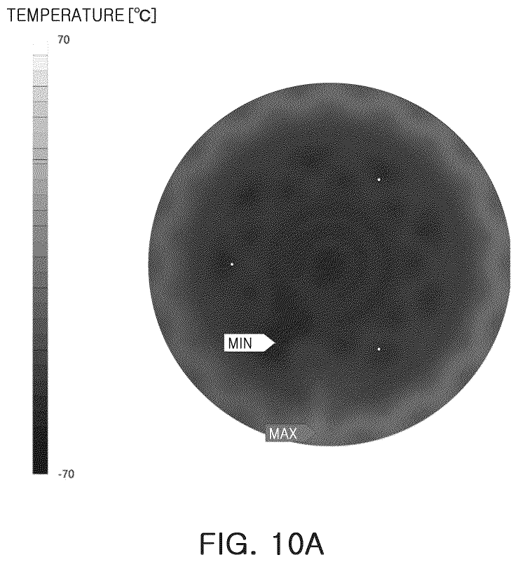

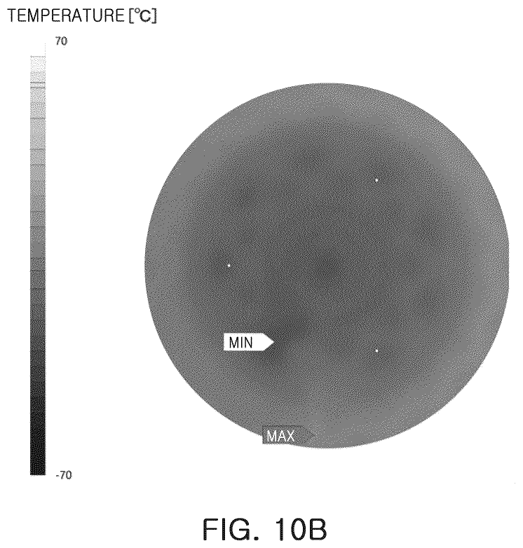

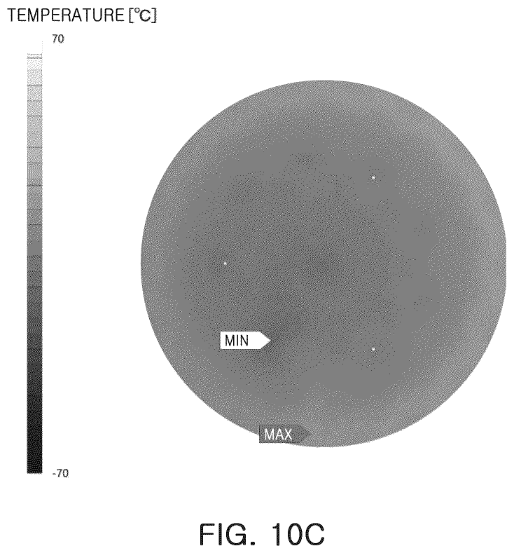

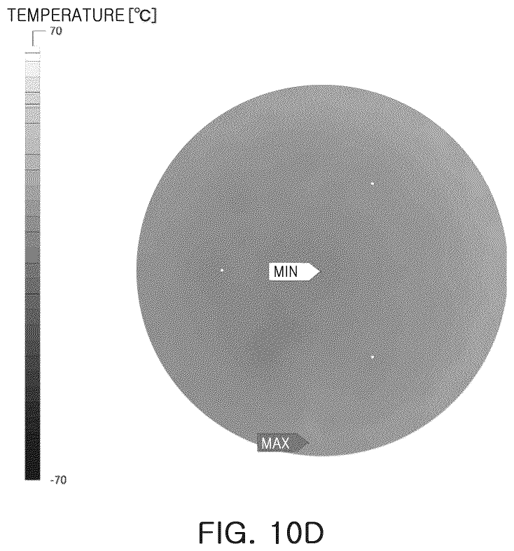

FIGS. 10A-10D are diagrams illustrating simulation results of the comparative example and shows that at a relatively low temperature, the relatively low-temperature fluid (first fluid) was distributed in the second direction from the outer circumferential side of the flow path toward the central side, and when the temperature increased, the relatively high-temperature fluid (second fluid) was distributed in the second direction from the outer circumferential side of the flow path toward the central side. That is, in the comparative example, the distribution direction of the first fluid and the distribution direction of the second fluid were configured to be in the same direction. The distribution speed of each fluid was configured to be constant.

In the temperature distribution simulation, the temperature distribution (temperature [° C.]) was calculated after 10 seconds (FIG. 9A, FIG. 10A), 20 seconds (FIG. 9B, FIG. 10B), 30 seconds (FIG. 9C, FIG. 10C), and 60 seconds (FIG. 9D FIG. 10D) when the first fluid was controlled to −70° C., the second fluid was controlled to 70° C., and distributed to the flow path 15 illustrated in FIGS. 3A and 3B.

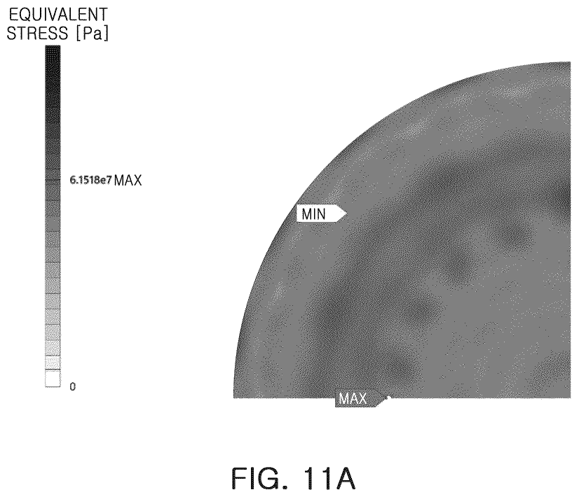

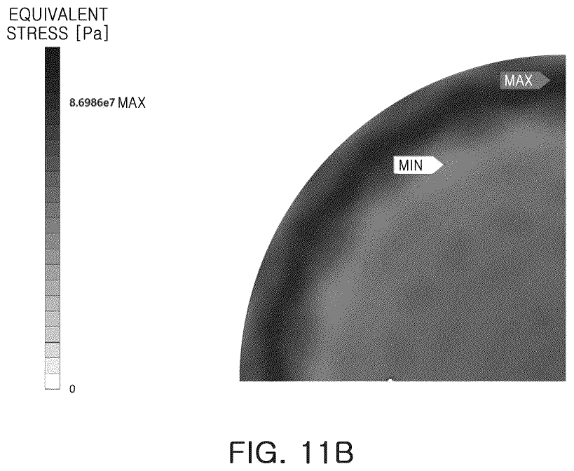

In the distribution of stress simulation, in the example embodiment, as illustrated in FIG. 11A, the distribution of stress (equivalent stress [Pa]) of the mounting surface of the electrostatic chuck in the state illustrated in FIG. 9A in which the temperature difference was largest was measured, and in the comparative example, as illustrated in FIG. 11B, the distribution of stress (equivalent stress [Pa]) measured in the state illustrated in FIG. 10A (comparative example) in which the temperature difference was largest.

The results of the comparison were as below.

When comparing the example embodiment (FIGS. 9A-9D) with the comparative example (FIGS. 10A-10D), it was confirmed that the temperature unevenness of the electrostatic chuck was suppressed when the first fluid and the second fluid were distributed in the opposite direction than when the second fluid was distributed in the same direction as the first fluid.

In the distribution of stress simulation, the distribution of stress in the comparative example was a maximum of 86.9 MPa as illustrated in FIG. 11B. In contrast, the distribution of stress in the example embodiment was a maximum of 61.5 MPa as illustrated in FIG. 11A. In the comparative example, the relatively low-temperature first fluid and the relatively high-temperature second fluid were distributed in the same direction, and in the example embodiment, the relatively low-temperature first fluid was distributed in the first direction and the relatively high-temperature second fluid was distributed in the second direction, which is the opposite direction to the first fluid. In the example embodiment, considering that the temperature unevenness was corrected or reduced as compared to the comparative example, it was confirmed that the stress caused by the temperature unevenness was reduced by controlling the direction of the distribution of fluid.

Ceramics may have very low tensile strength with respect to compressive strength. In the comparative example, because the relatively low-temperature first fluid and the relatively high-temperature second fluid were distributed in the same direction (e.g., the second direction), the outer circumferential side of the electrostatic chuck became high temperature and expanded toward the outer circumferential side, and the inner circumferential side became low temperature and did not expand relatively. Accordingly, it may be assumed that the electrostatic chuck in the comparative example may generate tensile stress in the component and may be highly likely to be broken by thermal stress. In contrast, in the example embodiment, because the relatively low-temperature first fluid was distributed in the first direction and the relatively high-temperature second fluid was distributed in the second direction, which is the opposite direction to the first fluid, the outer circumferential side of the electrostatic chuck did not become low temperature and did not expand, and the inner circumferential side expanded toward the outer circumferential side. Accordingly, the electrostatic chuck in the example embodiment may generate compressive stress in the component, but because the chuck is formed of or includes ceramics having relatively great compressive strength, it may be assumed that the chuck may reduce or prevent damages due to thermal stress. As described above, it is confirmed that the electrostatic chuck may effectively reduce or prevent damages caused by temperature changes by appropriately controlling the distribution direction of fluids having different temperatures.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

According to the aforementioned example embodiments, damages to the components caused by rapid temperature changes may be reduced or prevented during temperature control, and the temperature control time may be shortened.

While some example embodiments have been illustrated and described above, it will be apparent to those skilled in the art that modifications and variations could be made without departing from the scope of the present disclosure as defined by the appended claims.

What is claimed is:

1. A temperature control system connected to a plasma processing device, which is configured to perform plasma etching on a work in a vacuum chamber,
wherein the plasma processing device including:
a temperature control base bonded to a bottom of a maintenance plate in the vacuum chamber, the temperature control base including a flow path through which fluid is distributed, the maintenance plate being in the vacuum chamber and configured to support the work thereon and fixed to a lower body of the vacuum chamber,
wherein the temperature control system including:
a first chiller configured to supply a first fluid controlled to a first temperature;
a second chiller configured to supply a second fluid controlled to a second temperature different from the first temperature; and
a fluid supply control unit configured to selectively supply the first fluid from the first chiller or the second fluid from the second chiller to the temperature control base,
wherein the fluid supply control unit includes a distribution-direction switching unit configured to control a distribution direction of each of the first fluid and the second fluid, and
wherein the distribution-direction switching unit is configured to distribute the second fluid in a first direction when the temperature is increased, and distribute the first fluid in a second direction when the temperature is decreased, the first direction being from a central side of the temperature control base toward an outer circumferential side of the temperature control base, the second direction being from the outer circumferential side of the temperature control base toward the central side of the temperature control base.

2. The temperature control system of claim 1, further comprising:
a storage unit being upstream of the first chiller and the second chiller, the storage unit configured to store a return fluid from the temperature control base, adjust a temperature of the return fluid to be equal to a control temperature of the first chiller or the second chiller, and return the fluid to the first chiller or the second chiller.

3. The temperature control system of claim 2, wherein the storage unit includes:
a first storage unit being upstream of the first chiller, the first storage unit configured to store the fluid from the temperature control base, adjust a temperature of the return fluid to be equal to a control temperature of the first chiller, and return the fluid to the first chiller, and
a second storage unit being upstream of the second chiller, the second storage unit configured to store the return fluid from the temperature control base, adjust the temperature of the return fluid to be equal to a control temperature of the second chiller, and return the fluid to the second chiller.

4. The temperature control system of claim 3, wherein
the first storage unit is configured to adjust the temperature of the stored return fluid to be equal to a control temperature of the first chiller by allowing the fluid to circulate between the first chiller and the first storage unit, and
wherein the second storage unit is configured to adjust the temperature of the stored return fluid to be equal to a control temperature of the second chiller by allowing the fluid to circulate between the second chiller and the second storage unit.

5. The temperature control system of claim 1, further comprising:
a common storage unit configured to store a return fluid from the temperature control base,
wherein when a temperature of the return fluid stored in the common storage unit is different from the control temperature of one of the first chiller or the second chiller, the common storage unit is configured to store the return fluid and distribute fluid of the same temperature as the first chiller or the second chiller, and
wherein when the temperature of the return fluid stored in the common storage unit becomes equal to the control temperature of the one of the first chiller or the second chiller, the temperature control system is configured to distribute the return fluid directly to the one of the first chiller or the second chiller.

6. The temperature control system of claim 5, wherein the common storage unit is configured to adjust the stored return fluid to a control temperature of the first chiller by allowing the fluid to circulate between the first chiller and the common storage unit during a high-temperature maintenance operation, and to adjust the stored return fluid to a control temperature of the second chiller by allowing the fluid to circulate between the second chiller and the common storage unit while a low temperature is maintained.

7. The temperature control system of claim 1, further comprising:
a gas supply unit configured to distribute an inert discharge gas to the flow path and discharge the fluid in the flow path when the fluid distributed to the temperature control base is switched to a different fluid.

8. The temperature control system of claim 7, further comprising:
a discharge fluid storage unit connected to the distribution-direction switching unit and configured to store a return fluid, which is discharged from the flow path by the gas supply unit supplying a discharge gas to the flow path.

9. The temperature control system of claim 8, wherein the temperature control system is configured to return the return fluid stored in the discharge fluid storage unit to the first chiller or the second chiller.

10. The temperature control system of claim 2, wherein, when a temperature of the fluid returning from the flow path becomes equal to a control temperature of the first chiller or the second chiller, the temperature control system is configured to return the return fluid to the first chiller or the second chiller through a bypass path without passing through the storage unit.

11. The temperature control system of claim 5, wherein, when the fluid returned from the flow path becomes equal to a control temperature of the first chiller or the second chiller, the temperature control system is configured to return the return fluid to the first chiller or the second chiller through a bypass path without passing through the common storage unit.

12. The temperature control system of claim 1, wherein
the flow path extends in a circular manner from the outer circumferential side to the central side inside the temperature control base and includes a first distribution port and a second distribution port, the first distribution port configured to direct the fluid to a central side of the flow path when distribution of fluid is initiated, the second distribution port configured to direct the fluid to an outer circumferential side of the flow path when distribution is initiated, and
the distribution-direction switching unit is configured to
distribute the second fluid in a first direction from the first distribution port of the temperature control base to the second distribution port of the temperature control base when a temperature rises, and
distribute the first fluid in a second direction from the second distribution port toward the first distribution port of the temperature control base when a temperature is lowered.

13. The temperature control system of claim 1, wherein the maintenance plate is configured as an electrostatic chuck, the electrostatic chuck having a plurality of convex portions thereon and including an electrode configured to absorb and maintain the work by electrostatic attraction.

14. A temperature control system connected to a plasma processing device, which is configured to perform plasma etching on a work in a vacuum chamber,
wherein the plasma processing device including:
a temperature control base bonded to a bottom of a maintenance plate in the vacuum chamber, the maintenance plate being in the vacuum chamber and configured to support the work thereon and fixed to a lower body of the vacuum chamber, and the temperature control base including a flow path through which fluid is distributed, and
wherein the temperature control system including:
a first chiller configured to supply a first fluid having a first temperature;
a second chiller configured to supply a second fluid having a second temperature higher than the first temperature;
a temperature adjustment unit configured to heat or cool the first fluid or the second fluid flowing into the temperature control base; and
a distribution-direction switching unit configured to control a distribution direction of each of the first fluid and the second fluid,
wherein the distribution-direction switching unit is configured to distribute the second fluid in a first direction in a temperature raising operation, and distribute the first fluid in a second direction in a temperature lowering operation, the first direction being from a central side of the temperature control base toward an outer circumferential side of the temperature control base, the second direction being from the outer circumferential side of the temperature control base toward the central side of the temperature control base.

15. The temperature control system of claim 14, wherein the temperature adjustment unit is configured to cool the first fluid to a temperature lower than a first target temperature.

16. The temperature control system of claim 14, wherein the temperature adjustment unit is configured to heat the second fluid to a temperature higher than a second target temperature.

17. The temperature control system of claim 16, further comprising:
a high-temperature storage unit configured to store a third fluid adjusted to a temperature higher than the second target temperature and including a fluid distribution port configured to supply the third fluid,
wherein the high-temperature storage unit is between the temperature control base and the distribution-direction switching unit.

18. The temperature control system of claim 17, wherein the fluid distribution port of the high-temperature storage unit is between the temperature control base and the distribution-direction switching unit.

19. The temperature control system of claim 17, wherein, when a temperature rise is initiated, the distribution-direction switching unit is configured to stop distribution of the third fluid, and then distribute the second fluid in the first direction.

20. A temperature control system connected to a plasma processing device, which is configured to perform plasma etching on a work in a vacuum chamber,
wherein the plasma processing device including:
a temperature control base bonded to a bottom of a maintenance plate in the vacuum chamber, the temperature control base including a flow path through which fluid is distributed, the maintenance plate being in the vacuum chamber and configured to support the work thereon and fixed to a lower body of the vacuum chamber, and
wherein the temperature control system including:
a first chiller configured to supply a first fluid controlled to a first temperature;
a first valve between the first chiller and the temperature control base;
a second chiller configured to supply a second fluid controlled to a second temperature different from the first temperature;
a second valve between the second chiller and the temperature control base; and
a fluid supply control unit configured to selectively supply at least one of the first fluid from the first chiller or the second fluid from the second chiller to the temperature control base,
wherein the fluid supply control unit includes a distribution-direction switching unit configured to control a distribution direction of each of the first fluid and the second fluid,
wherein, in a temperature raising operation, the second valve is configured to be opened to allow distribution of the second fluid to the temperature control base, and the distribution-direction switching unit is configured to distribute the second fluid in a first direction from a central side of the temperature control base to an outer circumferential side, and
wherein, in a temperature lowering operation, the first valve is configured to be opened to allow distribution of the first fluid the temperature control base, and the distribution-direction switching unit is configured to distribute the first fluid in a second direction from the outer circumferential side of the temperature control base toward the central side of the temperature control base.
